(19) United States
(12) Patent Application Publication
(10) Pub. No.: US 2026/0262298 A1
(43) Pub. Date: Sep. 3, 2026

(54) SEMICONDUCTOR DEVICE

(71) Applicant: ROHM CO., LTD., Kyoto (JP)

(72) Inventor: Keishi WATANABE, Kyoto (JP)

(73) Assignee: ROHM CO., LTD., Kyoto (JP)

(21) Appl. No.: 19/545,680

(22) Filed: Feb. 20, 2026

(30) Foreign Application Priority Data
Feb. 28, 2025 (JP) 2025-031898

(51) Int. Cl. H10D 89/60; H10D 8/25; H10D 8/50

(52) U.S. Cl. CPC H10D 89/611; H10D 8/25; H10D 8/50

(57) ABSTRACT

A semiconductor device includes a semiconductor substrate, an intermediate region including a stacked structure in which a first semiconductor region has stacked thereon a second semiconductor region, and a stacked structure in which a third semiconductor region has stacked thereon a fourth semiconductor region. The impurity concentration of the second semiconductor region is lower than those of the first semiconductor region and the third semiconductor region. The fourth semiconductor region and the third semiconductor region form a Zener diode. The third semiconductor region forms a PIN diode with the second semiconductor region, which is the uppermost layer of the intermediate region. The first semiconductor region and the second semiconductor region form a PIN diode. The first semiconductor region, which is the lowermost layer of the intermediate region, forms a Zener diode with the semiconductor substrate.

### CROSS REFERENCE TO RELATED APPLICATION

This application is based upon and claims the benefit of priority of the prior Japanese Patent Application No. 2025-031898, filed on February 28, 2025, the entire contents of which are incorporated herein by reference.

### Technical Field

The present disclosure relates to a semiconductor device.

### Background Art

Semiconductor integrated circuits such as LSIs (Large Scale Integration) utilize semiconductor devices (hereinafter also referred to as "overvoltage protection elements") to protect the internal circuit from unexpected surge voltages applied to the input and output terminals due to static electricity or fluctuations in power supply voltage. The overvoltage protection elements include ESD (electrostatic discharge) protection elements. Examples of the overvoltage protection devices include diodes or thyristors, such as transient voltage suppressor (TVS) diodes, and NPN or PNP bipolar transistors.

### Prior Art Documents

### Patent Documents

Patent Document 1: Japanese Patent Application Laid-open Publication No. 2021-190531

### BRIEF DESCRIPTION OF THE DRAWINGS

FIG. 1 is a schematic cross-sectional view of a semiconductor device according to Embodiment 1.

FIG. 2 is a schematic plan view of the semiconductor device according to Embodiment 1.

FIG. 3 is a schematic cross-sectional view illustrating a configuration example of a semiconductor body included in the semiconductor device according to Embodiment 1.

FIG. 4 is an equivalent circuit diagram of the semiconductor device according to Embodiment 1.

FIG. 5 is a schematic cross-sectional view for explaining an operation of the semiconductor device according to Embodiment 1.

FIG. 6 is an equivalent circuit diagram for explaining current paths in the operations of the semiconductor device illustrated in FIG. 5.

FIG. 7 is a schematic cross-sectional view for explaining another operation of the semiconductor device according to Embodiment 1.

FIG. 8 is an equivalent circuit diagram for explaining current paths in the operations of the semiconductor device illustrated in FIG. 7.

FIG. 9 is a schematic diagram illustrating an example of using the semiconductor device according to Embodiment 1 as an overvoltage protection element.

FIG. 10 is a schematic cross-sectional view illustrating the configuration of a semiconductor device of a comparison example.

FIG. 11 is an equivalent circuit diagram of the semiconductor device of the comparison example illustrated in FIG. 10.

FIG. 12 is a schematic cross-sectional view illustrating the configuration of a modification example of the semiconductor device of the comparison example.

FIG. 13 is an equivalent circuit diagram of the semiconductor device of the comparison example illustrated in FIG. 12.

FIG. 14 is a schematic cross-sectional view illustrating a configuration of a semiconductor device according to Embodiment 2.

FIG. 15 is a schematic plan view of the semiconductor device according to Embodiment 2.

FIG. 16 is a schematic cross-sectional view illustrating a configuration example of a semiconductor body included in the semiconductor device according to Embodiment 2.

FIG. 17 is an equivalent circuit diagram of the semiconductor device according to Embodiment 2.

FIG. 18 is a schematic cross-sectional view for explaining an operation of the semiconductor device according to Embodiment 2.

FIG. 19 is a schematic cross-sectional view for explaining another operation of the semiconductor device according to Embodiment 2.

FIG. 20 is a schematic cross-sectional view illustrating a configuration of a semiconductor device according to Modification Example 1 of Embodiment 2.

FIG. 21 is a schematic plan view of the semiconductor device according to Modification Example 1 of Embodiment 2.

FIG. 22 is an equivalent circuit diagram of the semiconductor device according to Modification Example 1 of Embodiment 2.

FIG. 23 is a schematic cross-sectional view illustrating a configuration of a semiconductor device according to Modification Example 2 of Embodiment 2.

FIG. 24 is a schematic cross-sectional view illustrating the configuration of a semiconductor device according to Embodiment 3.

FIG. 25 is a schematic plan view of the semiconductor device according to Embodiment 3.

FIG. 26 is a schematic cross-sectional view illustrating a configuration example of a semiconductor body included in the semiconductor device according to Embodiment 3.

FIG. 27 is an equivalent circuit diagram of the semiconductor device according to Embodiment 3.

FIG. 28 is a schematic cross-sectional view illustrating a configuration of a semiconductor device according to Modification Example 1 of Embodiment 3.

FIG. 29 is an equivalent circuit diagram of the semiconductor device according to Modification Example 1 of Embodiment 3.

FIG. 30 is a schematic cross-sectional view illustrating a configuration of a semiconductor device according to Modification Example 2 of Embodiment 3.

FIG. 31 is an equivalent circuit diagram of a semiconductor device according to another embodiment.

FIG. 32 is an equivalent circuit diagram of another semiconductor device according to another embodiment.

FIG. 33 is an equivalent circuit diagram of yet another semiconductor device according to another embodiment.

### DETAILED DESCRIPTION OF EMBODIMENTS

Next, embodiments of the present disclosure will be explained with reference to the drawings. In the descriptions of the diagrams below, the same reference character is given to the same or equivalent parts. However, the drawings are schematic and the relationships between thicknesses and planar dimensions, the ratio of the respective thicknesses and the like differ from the reality. Needless to say, the relationship or ratio of the respective dimensions may differ between the respective drawings.

Furthermore, the embodiments described below are merely examples of devices or methods for embodying the technical concept, and do not limit the shape, structure, arrangement, and the like of the components to those described below. Various modifications can be made to those embodiments without departing from the scope of claims.

### Embodiment 1

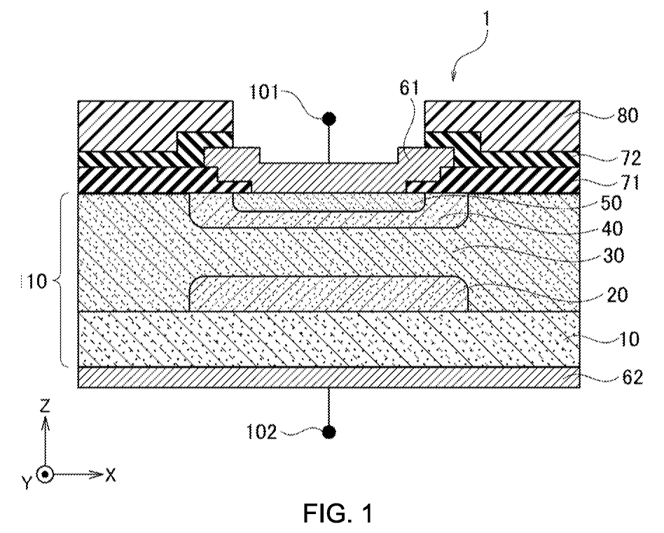

FIG. 1 shows a semiconductor device 1 according to Embodiment 1. The semiconductor device 1 includes a semiconductor substrate 10 of the first conductivity type, a first semiconductor region 20 of the second conductivity type disposed on the top surface of the semiconductor substrate 10, and a second semiconductor region 30 disposed on the semiconductor substrate 10 to cover the first semiconductor region 20 and having a conductivity type differing from that of the first semiconductor region 20. A third semiconductor region 40 of the second conductivity type is disposed on the top surface of the second semiconductor region 30, facing the first semiconductor region 20 through the second semiconductor region 30. A fourth semiconductor region 50 of the first conductivity type is embedded in a portion of the upper part of the third semiconductor region 40. The impurity concentration of the second semiconductor region 30 is lower than the impurity concentrations of the first semiconductor region 20 and the third semiconductor region 40. As shown in FIG. 1, the third semiconductor region 40 may be embedded in a portion of the upper part of the second semiconductor region 30.

As described above, the semiconductor device 1 has a layered structure in which the semiconductor substrate 10, the first semiconductor region 20, the second semiconductor region 30, the third semiconductor region 40, and the fourth semiconductor region 50 are stacked in this order. In the descriptions below, the region constituted of the semiconductor substrate 10, the first semiconductor region 20, the second semiconductor region 30, the third semiconductor region 40, and the fourth semiconductor region 50 is also referred to as a semiconductor body 110.

The first conductivity type and the second conductivity type are of opposite conductivity types. That is, if the first conductivity type is N type, the second conductivity type is P type, and if the first conductivity type is P type, the second conductivity type is N type. Therefore, a diode is configured in the semiconductor body 110 as follows. The semiconductor substrate 10 and the first semiconductor region 20 constitute a Zener diode. The first semiconductor region 20 and the second semiconductor region 30 constitute a PIN diode structure with a low impurity concentration. The second semiconductor region 30 and the third semiconductor region 40 constitute a PIN diode. The third semiconductor region 40 and the fourth semiconductor region 50 constitute a Zener diode. Zener diodes can be used even with high voltages, such as around 50V, and allow current to flow in both directions.

In the following descriptions, a case where the first conductivity type is N type and the second conductivity type is P type will be explained as an example. Also, the semiconductor device 1 will be explained assuming that second semiconductor region 30 has a different conductivity type from the P-type first semiconductor region 20, and is an N(-) type with an impurity concentration lower than those of the first semiconductor region 20 and the third semiconductor region 40. In this disclosure, in semiconductor regions of both P type and N type conductivity, regions whose conductivity type is indicated with a minus (-) sign have a relatively lower impurity concentration than regions without a sign, while regions whose conductivity type is marked with a plus (+) sign indicate a relatively higher impurity concentration than regions without a sign.

For example, the first semiconductor region 20 and the third semiconductor region 40 are P type diffusion layers with a thickness of approximately 0.5μm to 10μm and an impurity concentration of approximately 5E15/cm³ to 5E18/cm³. The second semiconductor region 30 is N type, with a thickness of approximately 3μm to 15μm and an impurity concentration of approximately 1E11/cm³ to 1E15/cm³. The second semiconductor region 30 may be an intrinsic semiconductor (i-type) with an impurity concentration lower than 1E11/cm³.

As shown in FIG. 1, the thickness direction of the semiconductor substrate 10 is defined as the Z-direction. In FIG. 1, the Z-direction is the vertical direction on the page. The plane perpendicular to the Z-axis is defined as the XY plane, which is determined by the X and Y directions. In FIG. 1, the X direction is the horizontal direction on the page, and the Y direction is the depth direction on the page. In the present disclosure, the direction in which the first semiconductor region 20 is located relative to the semiconductor substrate 10 in the Z direction is the upward direction, and the direction in which the semiconductor substrate 10 is located relative to the first semiconductor region 20 is defined as the downward direction. Furthermore, the surface facing upwards is called a top surface, and the surface facing downwards is called a bottom surface. For example, the top and bottom surfaces of the semiconductor substrate 10 are parallel to the XY plane.

A first insulating layer 71 is disposed on the top surface of the semiconductor body 110. An upper metal layer 61 is disposed on the top surface of the first insulating layer 71. An opening is formed in a portion of the first insulating layer 71, and the fourth semiconductor region 50 and the upper metal layer 61 are electrically connected through this opening. In other words, except for the region where the fourth semiconductor region 50 is exposed in the opening of the first insulating layer 71, the semiconductor body 110 and the upper metal layer 61 are electrically insulated from each other by the first insulating layer 71. A second insulating layer 72 is disposed covering the first insulating layer 71 and the upper metal layer 61, and a portion of the upper metal layer 61 is exposed through an opening formed in the second insulating layer 72. The upper metal layer 61 is electrically connected to a first external terminal 101 of the semiconductor device 1. The first insulating layer 71 and the second insulating layer 72 are interlayer insulating films, and serve to insulate wiring lines from each other in the semiconductor device 1 with a multilayer wiring structure.

For example, an aluminum (Al) film may be used for the upper metal layer 61. Alternatively, the upper metal layer 61 may use a laminated film consisting of a Ti film as the bottom layer, followed by an aluminum-copper (AlCu) film: 0.5μm to 5μm, a titanium nitride (TiN) film: 50nm to 150nm, and a titanium (Ti) film: 10nm to 50nm. The first insulating layer 71 may be a silicon dioxide (SiO₂) film with a thickness of 0.5μm to 6μm. The second insulating layer 72 may be a silicon nitride (SiN) film with a thickness of 0.5μm to 4μm.

A protective layer 80 is disposed on the top surfaces of the first insulating layer 71 and the second insulating layer 72. The protective layer 80 coats the surface of the semiconductor device 1, preventing it from being affected by the external environment as well as preventing the adhesion of contaminants. The protective layer 80 may be, for example, a polyimide film with a thickness of 2μm to 10μm.

A lower electrode layer 62 is disposed on the bottom surface of the semiconductor substrate 10 that has the first semiconductor region 20 on the top surface thereof. The lower electrode layer 62 uses the same metal material as the upper metal layer 61. The lower metal layer 62 is electrically connected to a second external terminal 102 of the semiconductor device 1.

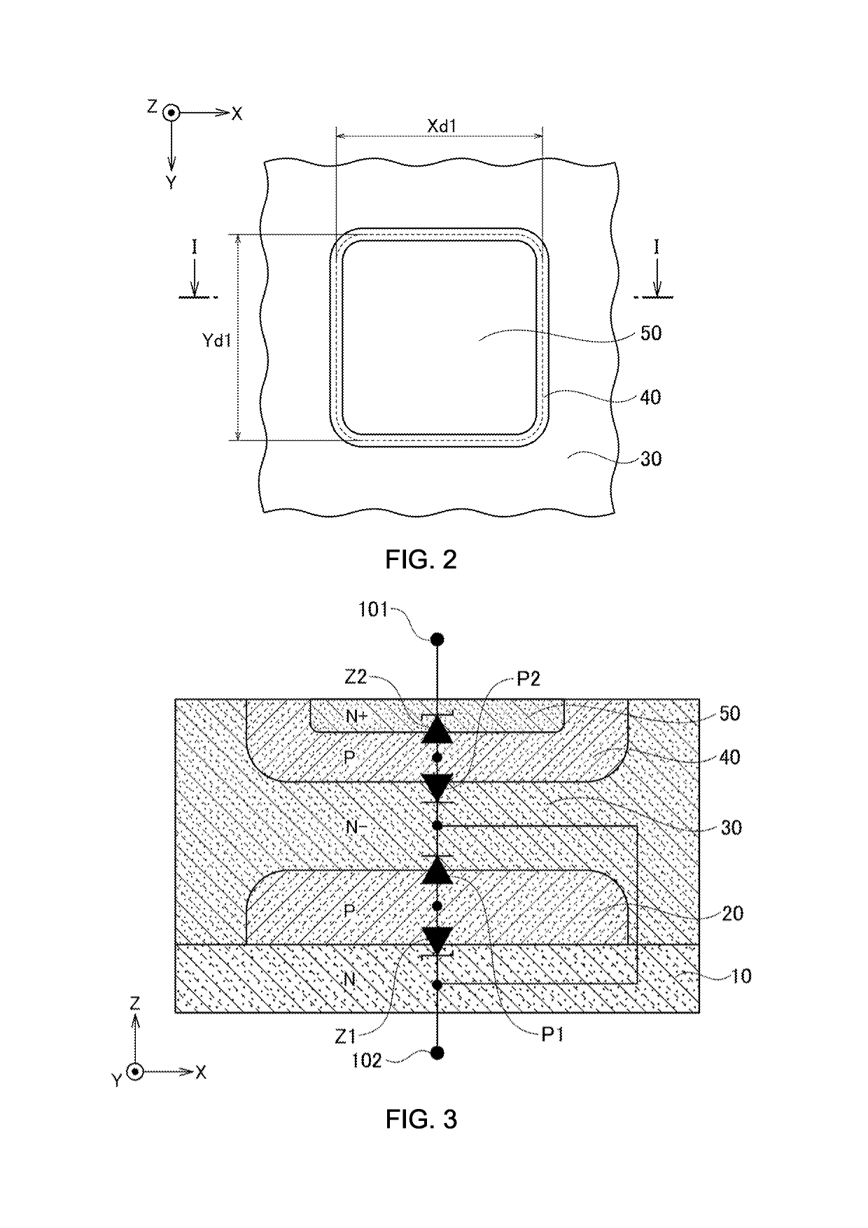

FIG. 2 shows a plan view of the semiconductor device 1, as seen from the Z direction, which is the direction normal to the top surface of the semiconductor substrate 10 (hereinafter also referred to as "plan view"). FIG. 1 is a cross-sectional view along the line I-I of FIG. 2. In FIG. 2, the protective layer 80, the first insulating layer 71, the second insulating layer 72, and the upper metal layer 61 are not shown; instead, the top surface of the semiconductor body 110 is displayed through these layers (the same applies to the plan views below). It is preferable that the area of the upper metal layer 61 that is in contact with the fourth semiconductor region 50 is located inside the outer edge of the fourth semiconductor region 50. This makes it possible to reduce the parasitic capacitance between the upper metal layer 61 and the fourth semiconductor region 50.

The dashed line shown in FIG. 2 indicates the outer edge of the upper metal layer 61 (the same applies to the plan views below).

In FIG. 2, the X-direction distance Xd1 is the length of the upper metal layer 61 along the X direction, and the Y-direction distance Yd1 is the length of the upper metal layer 61 along the Y direction. In Embodiment 1, Xd1 = 140μm and Yd1 = 140μm.

FIG. 3 illustrates the semiconductor body 110 where the first conductivity type is N type and the second conductivity type is P type.

As illustrated in FIG. 3, a first Zener diode Z1 is configured with the first semiconductor region 20 as the anode and the semiconductor substrate 10 as the cathode. A first PIN diode P1 is configured with the first semiconductor region 20 as the anode and the second semiconductor region 30 as the cathode. A second PIN diode P2 is configured with the third semiconductor region 40 as the anode and the second semiconductor region 30 as the cathode. A second Zener diode Z2 is configured with the third semiconductor region 40 as the anode and the fourth semiconductor region 50 as the cathode.

In the following descriptions, the first PIN diode P1 and the second PIN diode P2 may also be referred to as "PIN diode P” if it is not necessary to differentiate them from each other. The Zener diode Z1 and the Zener diode Z2 may also be referred to as “Zener diode Z” if it is not necessary to differentiate them from each other. The Zener diode Z functions as a voltage clamping type surge protection device.

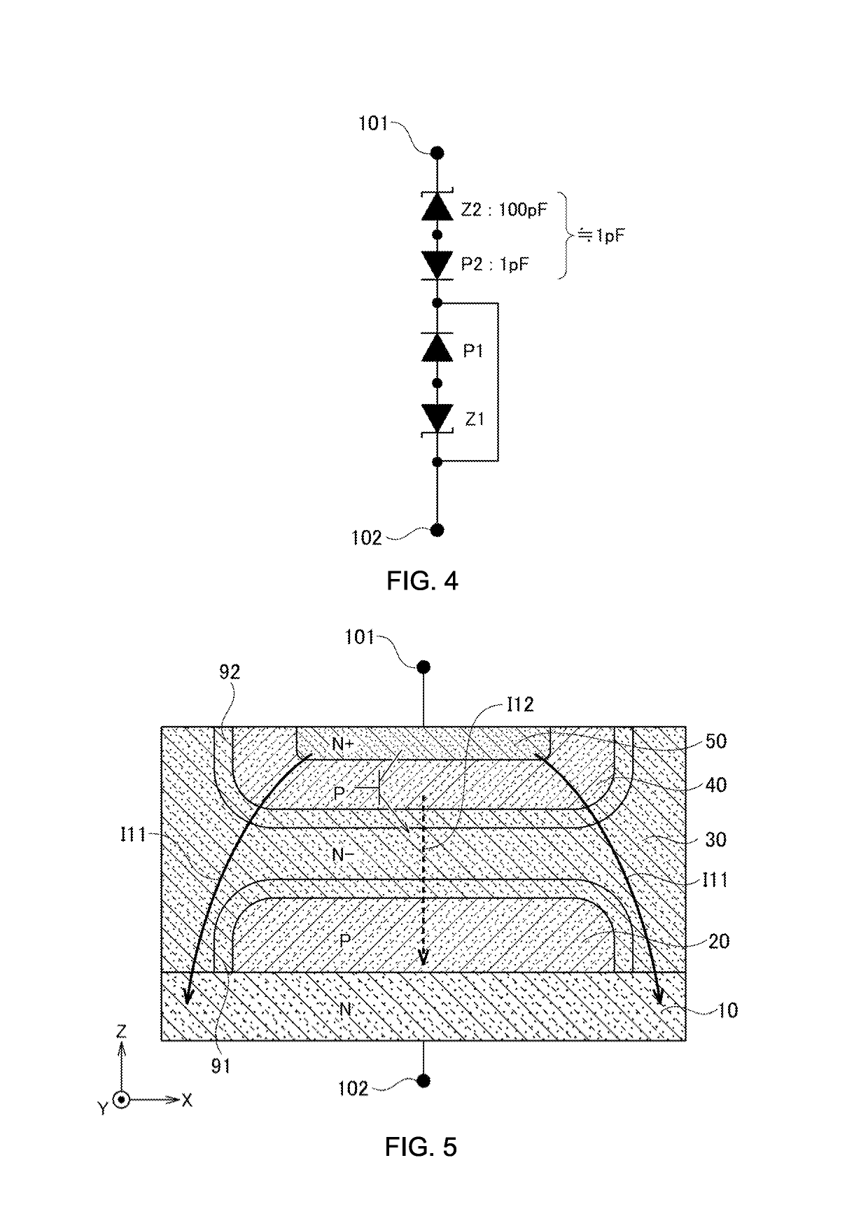

FIG. 4 illustrates an equivalent circuit diagram constituted of the PIN diodes P and Zener diodes Z included in the semiconductor device 1. The cathode of the second Zener diode Z2 is connected to the first external terminal 101, and the anode of the second Zener diode Z2 is connected to the anode of the second PIN diode P2. The cathode of the second PIN diode P2 is connected to the cathode of the first PIN diode P1, and the anode of the first PIN diode P1 is connected to the anode of the first Zener diode Z1. The cathode of the first Zener diode Z1 is connected to the second external terminal 102. However, in the semiconductor device 1 shown in FIG. 1, the second semiconductor region 30 is connected to the semiconductor substrate 10 outside the first semiconductor region 20. Therefore, the connection point between the cathode of the second PIN diode P2 and the cathode of the first PIN diode P1 is short-circuited to the second external terminal 102.

As described above, the semiconductor device 1 has a structure in which PIN diodes P and Zener diodes Z are stacked in the film thickness direction (Z direction). In the following descriptions, stacking the PIN diodes P and the Zener diodes Z in the direction of the film thickness is referred to as “vertical stacking.” Furthermore, the structure in which PIN diodes P and Zener diodes Z are stacked vertically is also referred to as a “vertically stacked structure.” The semiconductor device 1 having a vertically stacked structure can have a smaller plan-view area (hereinafter simply referred to as “area”).

FIG. 4 illustrates examples of capacitance values for the PIN diode P and Zener diode Z of the semiconductor device 1. The capacitance value of the PIN diode P is approximately 1pF, while the capacitance value of the Zener diode Z is approximately 100pF. Therefore, the total capacitance value of the semiconductor device 1 is approximately 1pF.

Next, the basic operation of the semiconductor device 1 will be explained.

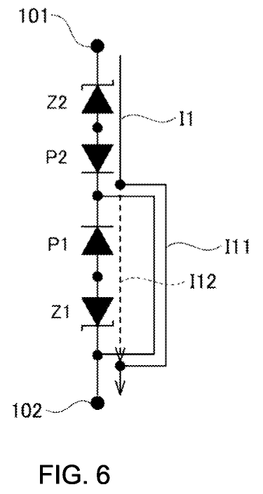

First, with reference to FIG. 5, the operation will be explained when a positive voltage is applied to the first external terminal 101. When a large positive voltage is applied to the first external terminal 101, the NPN transistor, which is constituted of the fourth semiconductor region 50, the third semiconductor region 40, and the second semiconductor region 30, undergoes a breakdown operation. As a result, first current I11 flows from the first external terminal 101 to the second external terminal 102. Furthermore, a lower depletion layer 91 is formed at the interface between the first semiconductor region 20 and the second semiconductor region 30, and an upper depletion layer 92 is formed at the interface between the second semiconductor region 30 and the third semiconductor region 40. This causes second current I12 to flow from directly beneath the fourth semiconductor region 50 to the semiconductor substrate 10, passing through the second semiconductor region 30 and the first semiconductor region 20. Therefore, as shown in the equivalent circuit diagram of FIG. 6, a combined current I1, which is the sum of the first current I11 and the second current I12, flows from the first external terminal 101 to the second external terminal 102.

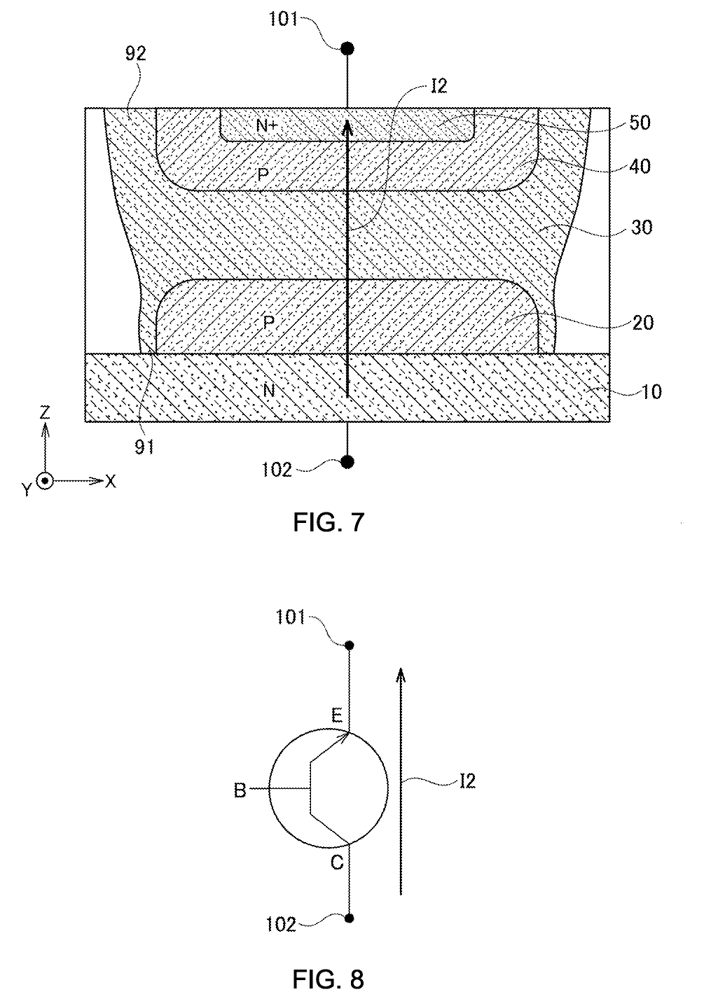

Next, with reference to FIG. 7, the operation will be explained when a positive voltage is applied to the second external terminal 102. When a large positive voltage is applied to the second external terminal 102, the width of the depletion layer closer to the first external terminal 101 increases, among the depletion layers formed at the interfaces between the second semiconductor region 30 and the P type semiconductor regions. That is, the upper depletion layer 92 formed at the interface between the second semiconductor region 30 and the third semiconductor region 40 extends downwardly toward the first semiconductor region 20. Then, as illustrated in FIG. 7, the second semiconductor region 30 is completely depleted between the first semiconductor region 20 and the third semiconductor region 40. As a result, the N region of the PNP region, which is constituted of the first semiconductor region 20, the second semiconductor region 30, and the third semiconductor region 40, disappears. Therefore, the entire first semiconductor region 20, second semiconductor region 30, and third semiconductor region 40 become electrically equivalent to a P type region.

This makes it possible to consider the entire semiconductor body 110 as an NPN transistor as shown in FIG. 8. As a result, when a large positive voltage is applied to the second external terminal 102, the NPN transistor undergoes a breakdown operation, and breakdown current I2 flows from the second external terminal 102 to the first external terminal 101.

As described above, the semiconductor device 1 can function as a bidirectional TVS. The impurity concentrations of the first semiconductor region 20, the second semiconductor region 30, and the third semiconductor region 40 are set to enable the operation described above. In other words, the impurity concentration of the semiconductor body 110 is set such that a depletion layer is formed across the entire thickness of the second semiconductor region 30, from its top surface to its bottom surface, when a predetermined voltage is applied between the semiconductor substrate 10 and the fourth semiconductor region 50.

In order to use the semiconductor device 1 as an overvoltage protection element, the impurity concentration of the semiconductor body 110 is set such that the second semiconductor region 30 is completely depleted when a surge voltage is applied to the first external terminal 101 or the second external terminal 102, for example. The impurity concentrations of the semiconductor substrate 10, the first semiconductor region 20, the second semiconductor region 30, and the third semiconductor region 40 may be set assuming a surge voltage (clamp voltage) is approximately 3V to 50V, for example. A Zener diode Z is formed depending on the surge voltage and required withstand voltage. On the other hand, the lower the impurity concentration in the second semiconductor region 30, the lower the capacitance value of the semiconductor device 1 can be. Regarding the film thickness of the second semiconductor region 30, if the thickness is 4μm or more, then it would not affect the capacitance value.

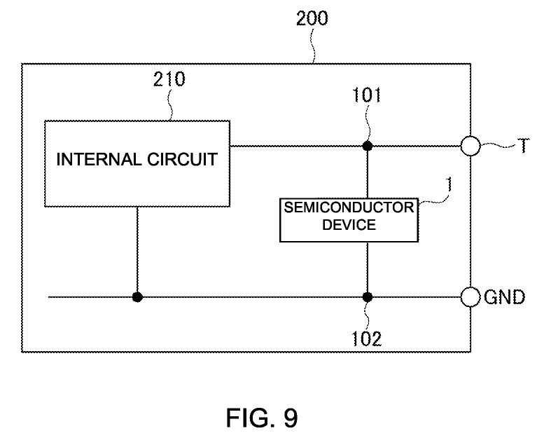

FIG. 9 illustrates an example of using the semiconductor device 1 as an overvoltage protection element. The first external terminal 101 of the semiconductor device 1 is connected to the input/output terminal T of the semiconductor integrated circuit 200, and the second external terminal 102 is connected to the ground electrode GND of the semiconductor integrated circuit 200. When a surge voltage or a voltage due to electrostatic discharge (ESD) is applied to the input/output terminal T of the semiconductor integrated circuit 200, current flows between the first external terminal 101 and the second external terminal 102 of the semiconductor device 1, as described with reference to FIGS. 5 and 7. As a result, the semiconductor device 1 protects an internal circuit 210 connected to the input/output terminal T from overvoltage applied to the input/output terminal T.

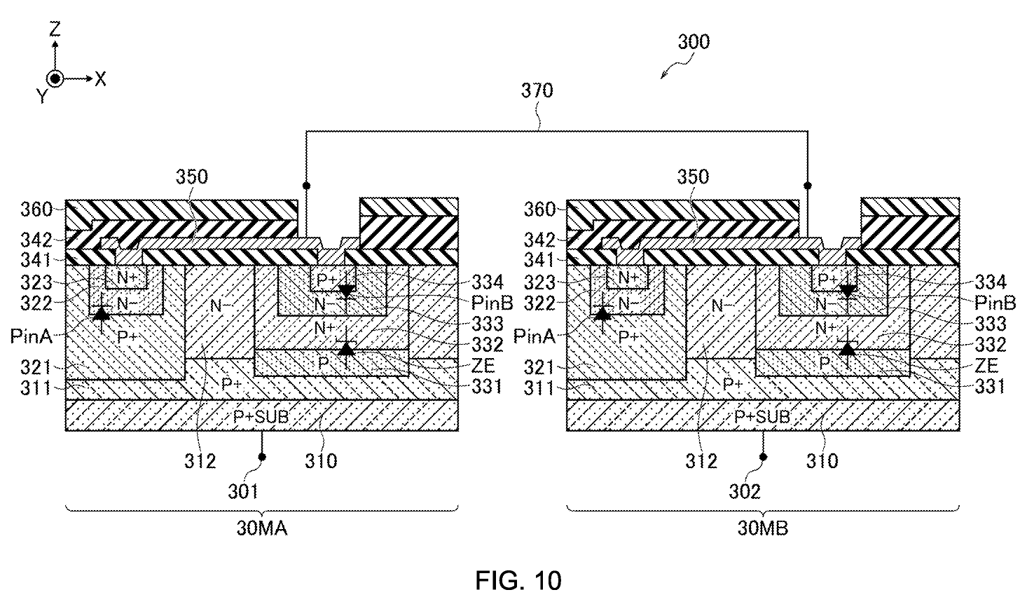

For comparison with the semiconductor device 1, FIG. 10 illustrates a semiconductor device of Comparison Example (hereinafter referred to as “comparative protection element 300”). The comparative protection element 300 shown in FIG. 10 includes a first protection element 30MA and a second protection element 30MB.

The comparative protection element 300 has a structure in which the first protection element 30MA and the second protection element 30MB, which have the same structure, are connected in series in opposite directions. In the following descriptions, the first protection element 30MA and the second protection element 30MB may collectively referred to as “protection element 30M” when it is not necessary to differentiate them from each other.

The protection element 30M has a structure in which a P+ layer 311 and an N- layer 312 are sequentially stacked on the top surface of a P+ SUB substrate 310. A P+ well region 321 is embedded from the top surface of the N- layer 312 to a portion of the upper part of the P+ layer 311. A first N- region 322 is embedded in a portion of the upper part of the P+ well region 321, and an N+ electrode region 323 is embedded in a portion of the upper part of the first N- region 322. As shown in FIG. 10, the first diode PinA is configured with the P+ well region 321 as the anode and the first N- region 322 as the cathode.

Separated from the P+ well region 321, an embedded P region 331 is positioned across a portion of the upper part of the P+ layer 311 and a portion of the lower part of the N- layer 312. An N+ well region 332 is embedded in the N- layer 312, extending from the top surface of the N- layer 312 to the top surface of the embedded P region 331. A second N- region 333 is embedded in a portion of the upper part of the N+ well region 332, and a P+ electrode region 334 is embedded in a portion of the upper part of the second N- region 333. As shown in FIG. 10, the second diode PinB is configured with the P+ electrode region 334 as the anode and the second N- region 333 as the cathode. Furthermore, a Zener diode ZE is configured with the embedded P region 331 as the anode and the N+ well region 332 as the cathode.

A silicon oxide layer 341 is formed on the top surface of the N- layer 312, and a metal layer 350 is disposed on the top surface of the silicon oxide layer 341. The metal layer 350 is an Al film, for example. The metal layer 350 is electrically connected to the N+ electrode region 323 and the P+ electrode region 334 through openings formed in the silicon oxide layer 341. The metal layer 350 is covered by a silicon nitride layer 342. The silicon nitride layer 342 is covered by a polyimide film 360. In the opening formed continuously in the silicon nitride layer 342 and the polyimide film 360, a portion of the metal layer 350 is exposed to the outside.

As shown in FIG. 10, the first protection element 30MA and the second protection element 30MB are connected in series in opposite directions by short-circuiting their respective metal layers 350 with a conductive wire 370. The P+ SUB substrate 310 of the first protection element 30MA is connected to a first terminal 301 of the comparative protection element 300, and the P+ SUB substrate 310 of the second protection element 30MB is connected to a second terminal 302 of the comparative protection element 300.

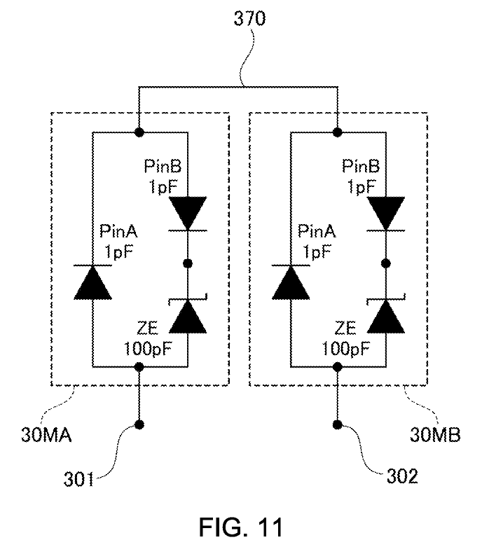

FIG. 11 is an equivalent circuit diagram of the comparative protection element 300 illustrated in FIG. 10. For example, by connecting the first terminal 301 between the input/output terminal and the internal circuit of the semiconductor integrated circuit, and connecting the second terminal 302 to the ground electrode, the comparative protection element 300 can be used as an overvoltage protection element for the semiconductor integrated circuit. By connecting the first protection element 30MA and the second protection element 30MB in series in opposite directions, the comparative protection element 300 functions as a bidirectional TVS. For example, when a positive voltage is applied to the first terminal 301, current flows from the first terminal 301 to the second terminal 302. When a positive voltage is applied to the second terminal 302, current flows from the second terminal 302 to the first terminal 301.

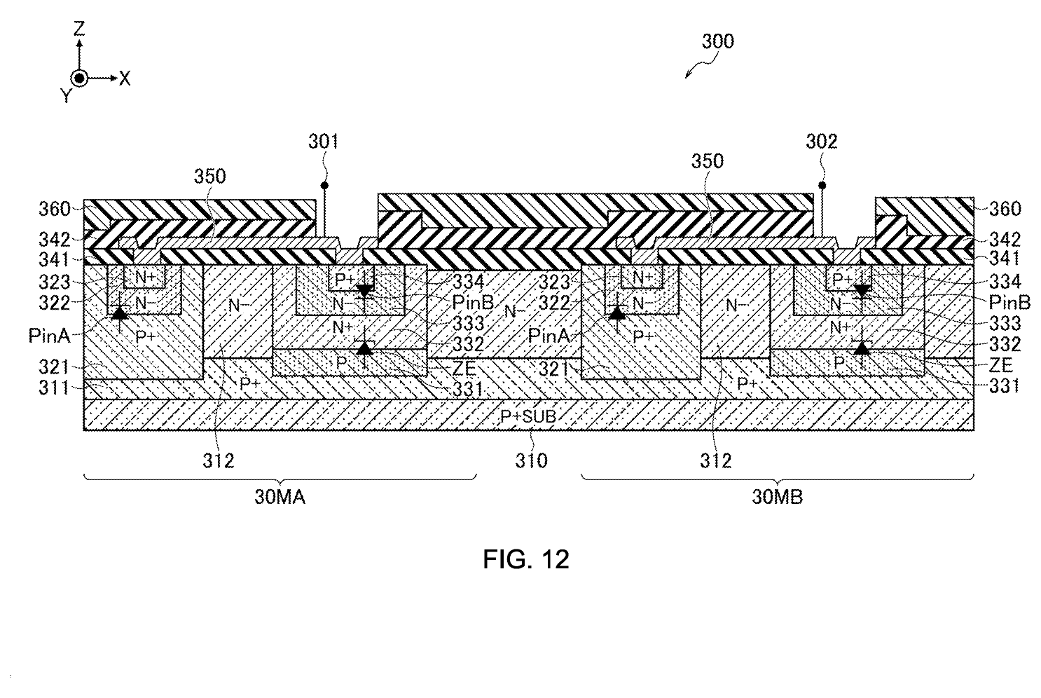

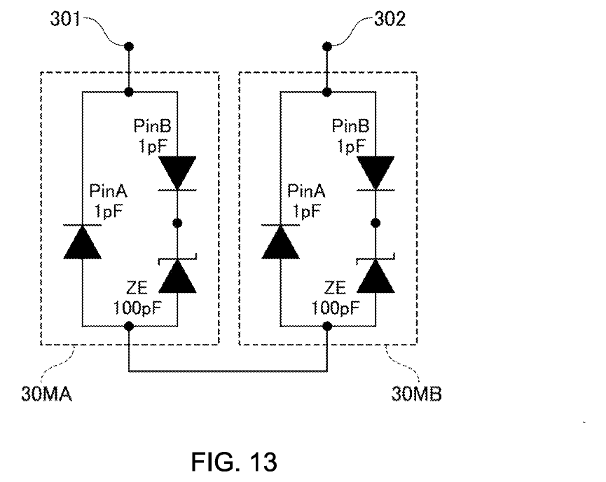

FIG. 12 is a modification example of the comparative protection element 300. In the comparative protection element 300 illustrated in FIG. 10, the first protection element 30MA and the second protection element 30MB are connected in series in opposite directions by the wire 370. On the other hand, in the comparative protection element 300 illustrated in FIG. 12, the first protection element 30MA and the second protection element 30MB are formed on the same P+ SUB substrate 310, P+ layer 311, and N- layer 312. In other words, the comparative protection element 300 shown in FIG. 12 has a structure in which the first terminal 301 of the first protection element 30MA and the second terminal 302 of the second protection element 30MB of FIG. 10 are short-circuited. In the comparative protection element 300 illustrated in FIG. 12, the metal layer 350 of the first protection element 30MA is connected to the first terminal 301, and the metal layer 350 of the second protection element 30MB is connected to the second terminal 302. The other configurations of the comparative protection element 300 of FIG. 12 are the same as those of the comparative protection element 300 of FIG. 10. FIG. 13 is an equivalent circuit diagram of the comparative protection element 300 illustrated in FIG. 12. In the comparative protection element 300 illustrated in FIG. 12 as well, by connecting the first protection element 30MA and the second protection element 30MB in series in opposite directions, the comparative protection element 300 functions as a bidirectional TVS.

As shown in FIGS. 11 and 13, when the capacitance values of the first diode PinA and the second diode PinB are 1pF, and the capacitance value of the Zener diode ZE is 100pF, the total capacitance value of each of the first protection element 30MA and the second protection element 30MB is approximately 2pF. Therefore, the total capacitance value of the comparative protection element 300, in which the first protection element 30MA and the second protection element 30MB are connected in series, is 1pF. As described above, the total capacitance value of the semiconductor device 1, which includes the vertically stacked structure, is approximately 1pF. Therefore, the total capacitance value of the semiconductor device 1 equals to that of the comparative protection element 300.

However, the protection element 30M of the comparative protection element 300 has a configuration in which the region formed by the first diode PinA and the region where the second diode PinB and the Zener diode ZE are stacked in the film thickness direction are arranged side by side in a plan view. This means that the area of the protection element 30M is greater than that of the semiconductor device 1. Furthermore, the comparative protection element 300, which has a configuration in which two protection elements 30M are arranged side by side in a plan view, requires a larger area.

In contrast, the semiconductor device 1 of Embodiment 1 has a structure in which the PIN diode P and the Zener diode Z are stacked vertically. By stacking the Zener diode vertically, the total area occupied by the Zener diode is half that of the comparative protection element 300. This makes it possible to make the area of the semiconductor device 1 smaller than that of the comparative protection element 300.

As described above, the semiconductor device 1 of Embodiment 1 can reduce the device area compared to the comparative protection element 300 by stacking the PIN diode P and the Zener diode Z vertically. As a result, with the semiconductor device 1, it is possible to reduce the area thereof while maintaining a low capacitance value and ensuring ESD and surge resistance.

### Embodiment 2

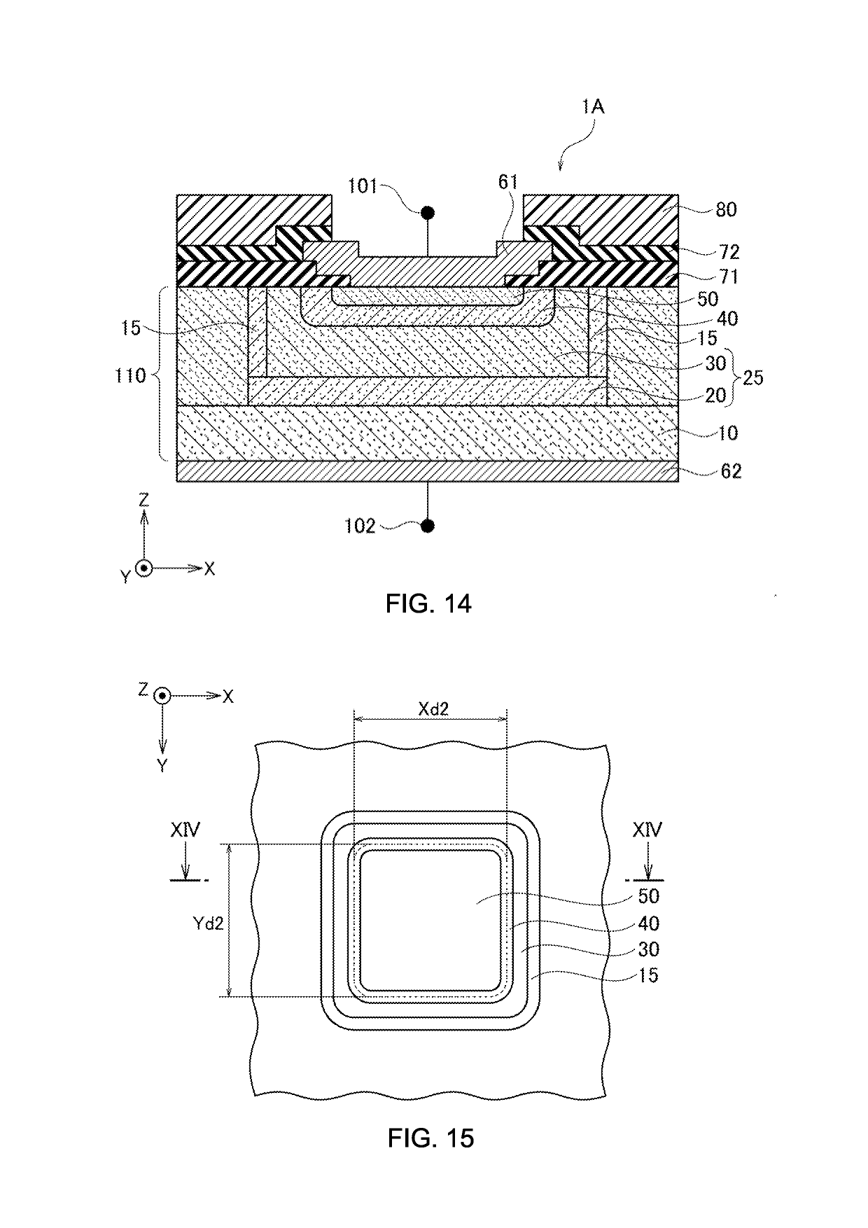

FIG. 14 illustrates a semiconductor device 1A according to Embodiment 2. The semiconductor device 1A illustrated in FIG. 14 includes a semiconductor substrate 10 of a first conductivity type and an intermediate region 25 disposed on the top surface of the semiconductor substrate 10. The intermediate region 25 includes at least one stacked structure (hereinafter also referred to as “intermediate stacked structure”) in which the first semiconductor region 20 of the second conductivity type has stacked thereon the second semiconductor region 30 with a conductivity type differing from that of the first semiconductor region 20. The semiconductor device 1A of FIG. 14 illustrates a case in which the intermediate region 25 includes a single intermediate stacked structure.

The semiconductor device 1A further includes the third semiconductor region 40 of the second conductivity type embedded in the upper part of the second semiconductor region 30, which is the uppermost layer of the intermediate region 25, and the fourth semiconductor region 50 of the first conductivity type embedded in a part of the upper portion of the third semiconductor region 40. The third semiconductor region 40 faces the semiconductor substrate 10 through the intermediate region 25. The impurity concentration of the second semiconductor region 30 is lower than the impurity concentrations of the first semiconductor region 20 and the third semiconductor region 40.

The semiconductor device 1A further includes an embedded region 15 that extends from the top surface of the intermediate region 25 toward the semiconductor substrate 10. The embedded region 15 is arranged to surround the third semiconductor region 40 without being electrically connected thereto, and defines the extent of the second semiconductor region 30 in a plan view. The embedded region 15 is a semiconductor of the second conductivity type, and the bottom of the embedded region 15 is connected to the first semiconductor region 20.

The semiconductor device 1A according to Embodiment 2 differs from the semiconductor device 1 illustrated in FIG. 1 in that it further includes the embedded region 15. Other configurations of the semiconductor device 1A are the same as those of Embodiment 1 illustrated in FIG. 1.

As described above, the semiconductor device 1A has a layered structure in which the semiconductor substrate 10, the intermediate region 25 having a stacked structure where the first semiconductor region 20 and the second semiconductor region 30 are stacked, the third semiconductor region 40, and the fourth semiconductor region 50 are stacked in this order. The semiconductor device 1A also includes the embedded region 15 of the second conductivity type arranged to surround the third semiconductor region 40. The fourth semiconductor region 50 and the third semiconductor region 40 form a Zener diode. The third semiconductor region 40 forms a PIN diode with the second semiconductor region 30, which is the uppermost layer of the intermediate region 25. The first semiconductor region 20 and the second semiconductor region 30 form a PIN diode. The first semiconductor region 20, which is the lowermost layer of the intermediate region 25, forms a Zener diode with the semiconductor substrate 10.

FIG. 15 is a plan view of the semiconductor device 1A illustrated in FIG. 14. FIG. 14 is a cross-sectional view along the line XIV-XIV of FIG. 15. In FIG. 15, the X-direction distance Xd2 is the length of the upper metal layer 61 along the X direction, and the Y-direction distance Yd2 is the length of the upper metal layer 61 along the Y direction. In Embodiment 2, Xd2 = 140μm and Yd2 = 140μm.

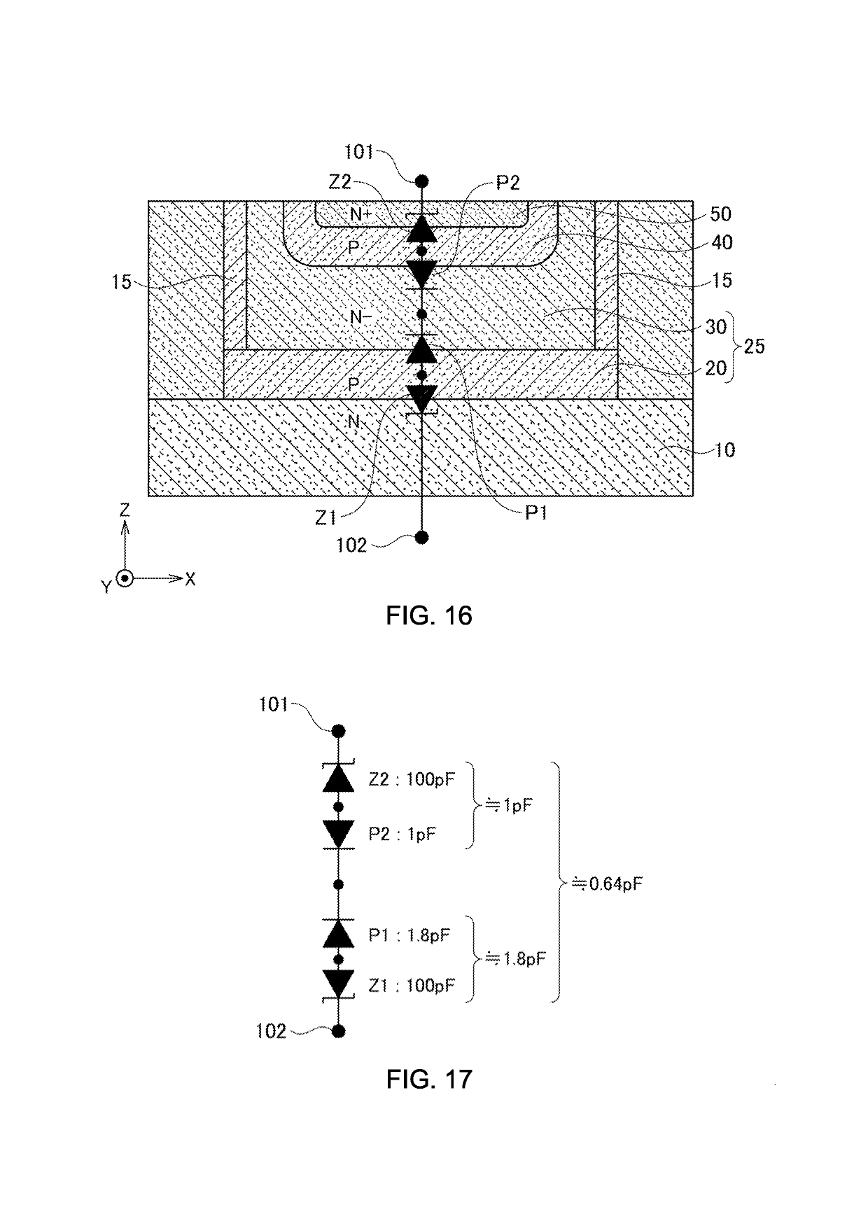

FIG. 16 illustrates the semiconductor body 100 of the semiconductor device 1A where the first conductivity type is N type and the second conductivity type is P type. As illustrated in FIG. 16, the first Zener diode Z1 is configured with the first semiconductor region 20 as the anode and the semiconductor substrate 10 as the cathode. The first PIN diode P1 is configured with the first semiconductor region 20 as the anode and the second semiconductor region 30 as the cathode. The second PIN diode P2 is configured with the third semiconductor region 40 as the anode and the second semiconductor region 30 as the cathode. The second Zener diode Z2 is configured with the third semiconductor region 40 as the anode and the fourth semiconductor region 50 as the cathode.

FIG. 17 illustrates an equivalent circuit diagram constituted of the PIN diode P and Zener diode Z included in the semiconductor device 1A. The cathode of the second Zener diode Z2 is connected to the first external terminal 101, and the anode of the second Zener diode Z2 is connected to the anode of the second PIN diode P2. The cathode of the second PIN diode P2 is connected to the cathode of the first PIN diode P1, and the anode of the first PIN diode P1 is connected to the anode of the first Zener diode Z1. The cathode of the first Zener diode Z1 is connected to the second external terminal 102.

The capacitance value of the PIN diode P and Zener diode Z included in the semiconductor device 1A is as shown in FIG. 17. That is, the capacitance value of the Zener diode Z is approximately 100pF. The capacitance value of the first PIN diode P1 is approximately 1.8pF, and the capacitance value of the second PIN diode P2 is approximately 1pF. Therefore, the total capacitance value of the semiconductor device 1A is approximately 0.64pF. Because the area of the first PIN diode P1 is larger than that of the second PIN diode P2, the capacitance value of the first PIN diode P1 is greater than that of the second PIN diode P2.

In the semiconductor device 1A of Embodiment 2, because the Zener diodes stacked vertically, the total area occupied by the Zener diodes is half that of the comparative protection element 300. Furthermore, as compared with the comparative protection element 300 that includes four PIN diodes, the semiconductor device 1A can reduce the area and capacitance value of the PIN diodes by half by removing the first diode PinA of the comparative protection element 300. As a result, with the semiconductor device 1A, it is possible to make the area thereof smaller than that of the comparative protection element 300 while maintaining a low capacitance value and ensuring ESD and surge resistance. Other configurations of the semiconductor device 1A are substantially the same as those of Embodiment 1, and the overlapping explanations are therefore omitted.

In the semiconductor device 1A, the third semiconductor region 40 is surrounded by the embedded region 15, resulting in a configuration where two PIN diodes are connected in series in opposite directions in the current path of the current that flows when a surge voltage is applied. Therefore, compared to the semiconductor device 1 of Embodiment 1, in which the second semiconductor region 30 is connected to the semiconductor substrate 10 and one PIN diode is included in the current path, the semiconductor device 1A can further reduce the capacitance value.

The basic operation of the semiconductor device 1A will be described below.

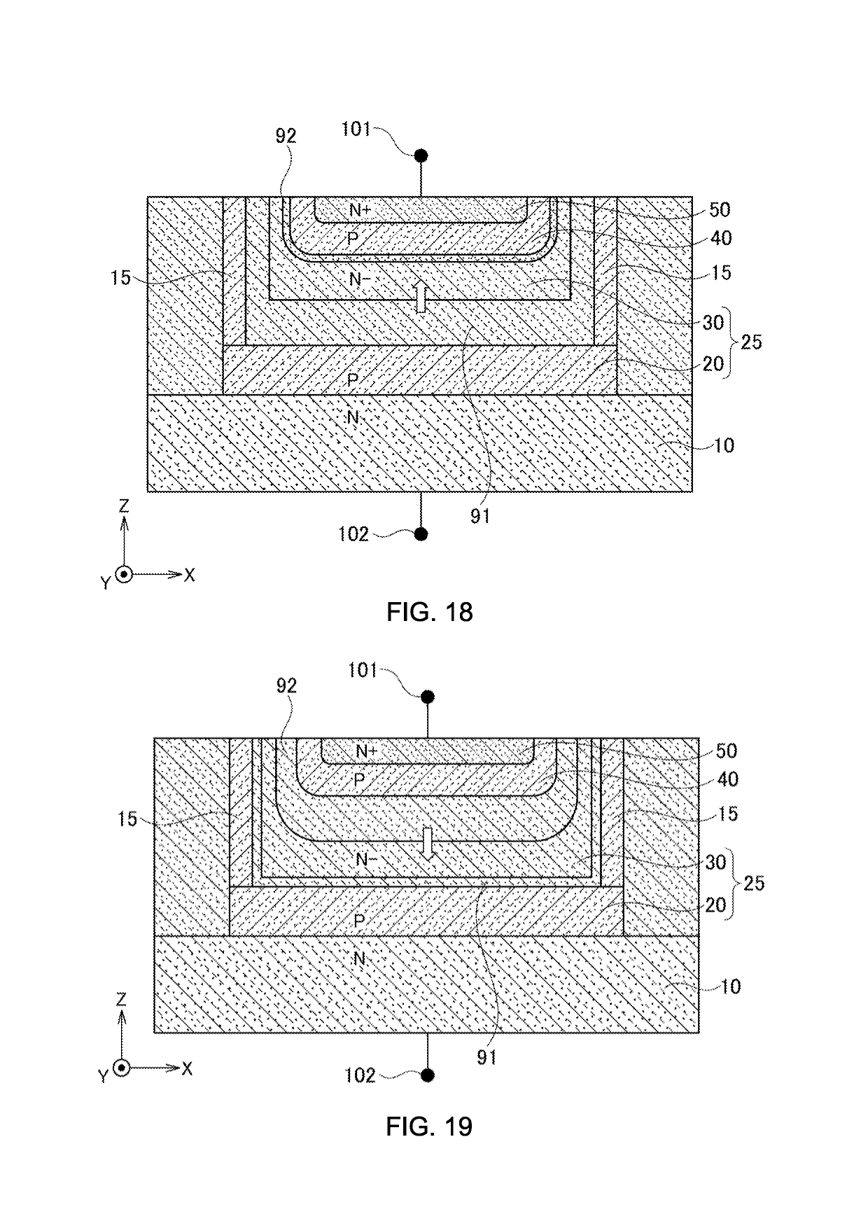

First, with reference to FIG. 18, the operation of the semiconductor device 1A when a positive voltage is applied to the first external terminal 101 is explained. When a large positive voltage is applied to the first external terminal 101, the width of the depletion layer closer to the second external terminal 102 increases, among the depletion layers formed at the interfaces between the second semiconductor region 30 and the P type semiconductor regions. That is, the lower depletion layer 91 formed at the interface between the first semiconductor region 20 and the second semiconductor region 30 extends upward toward the third semiconductor region 40. Then, when a large voltage (such as a surge voltage) is applied to the first external terminal 101, the second semiconductor region 30 is completely depleted between the first semiconductor region 20 and the embedded region 15, and the third semiconductor region 40. That is, the N region of the PNP region, which is constituted of the first semiconductor region 20, the second semiconductor region 30, and the third semiconductor region 40, disappears. Therefore, the entire first semiconductor region 20, second semiconductor region 30, and third semiconductor region 40 become electrically equivalent to the P type region.

This makes it possible to consider the entire semiconductor body 100 as an NPN transistor in a manner similar to FIG. 8. As a result, when a large positive voltage is applied to the first external terminal 101, the NPN transistor undergoes a breakdown operation, and breakdown current flows from the first external terminal 101 to the second external terminal 102. In this way, the semiconductor device 1A functions as an overvoltage protection element.

Next, with reference to FIG. 19, the operation of the semiconductor device 1A when a positive voltage is applied to the second external terminal 102 is explained. When a large positive voltage is applied to the second external terminal 102, the width of the depletion layer closer to the first external terminal 101 increases, among the depletion layers formed at the interfaces between the second semiconductor region 30 and the P type semiconductor regions. That is, the upper depletion layer 92 formed at the interface between the second semiconductor region 30 and the third semiconductor region 40 extends downward toward the first semiconductor region 20. Then, when a large voltage (such as a surge voltage) is applied to the second external terminal 102, the second semiconductor region 30 is completely depleted between the first semiconductor region 20 and the embedded region 15, and the third semiconductor region 40. That is, the N region of the PNP region, which is constituted of the first semiconductor region 20, second semiconductor region 30, and third semiconductor region 40, disappears. Therefore, the entire first semiconductor region 20, second semiconductor region 30, and third semiconductor region 40 become electrically equivalent to the P type regions.

This makes it possible to consider the entire semiconductor body 100 as an NPN transistor in a manner similar to FIG. 8. As a result, when a large positive voltage is applied to the second external terminal 102, the NPN transistor undergoes a breakdown operation, and breakdown current flows from the second external terminal 102 to the first external terminal 101. In this way, the semiconductor device 1A functions as an overvoltage protection element.

As described above, the semiconductor device 1A can function as a bidirectional TVS. In the semiconductor device 1A, the impurity concentration of the semiconductor body 100 may be set in a manner similar to the semiconductor device 1 of Embodiment 1. In other words, the impurity concentrations of the first semiconductor region 20, the second semiconductor region 30, and the third semiconductor region 40 may be set such that a depletion layer is formed from the top surface to the bottom surface of the second semiconductor region 30, when a predetermined voltage is applied between the semiconductor substrate 10 and the fourth semiconductor region 50. The second semiconductor region 30 may be an intrinsic semiconductor (i-type).

As described above, the semiconductor device 1A of Embodiment 2 can reduce the device area compared to the comparative protection element 300 by stacking the PIN diode P and the Zener diode Z vertically. As a result, with the semiconductor device 1A, it is possible to reduce the area thereof as compared with the comparative protection element 300 while maintaining a low capacitance value and ensuring ESD and surge resistance. Furthermore, the semiconductor device 1A has a structure in which two PIN diodes are connected in series, and thus, the capacitance value may be reduced as compared with the semiconductor device 1 of Embodiment 1 having one PIN diode.

### Modification Example 1

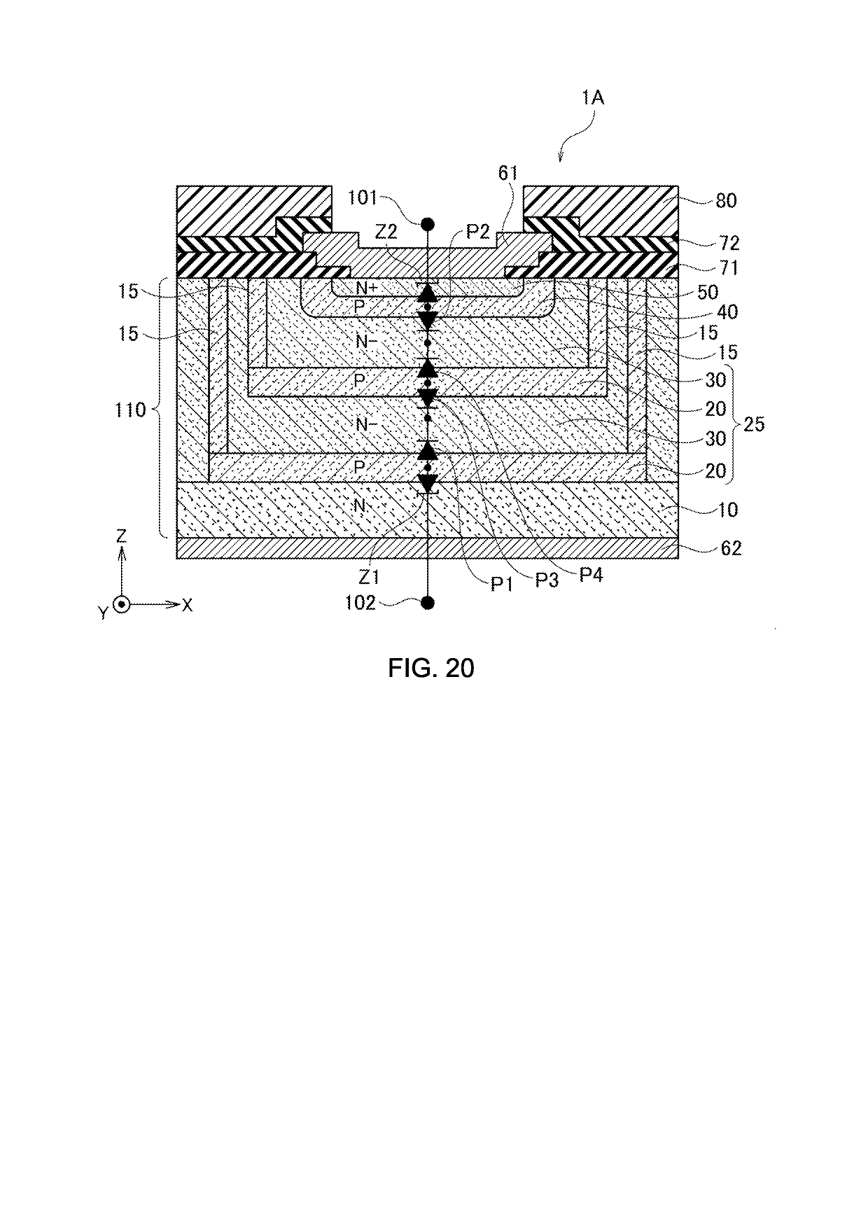

FIG. 20 illustrates a semiconductor device 1A according to Modification Example 1 of Embodiment 2. The intermediate region 25 of the semiconductor device 1A shown in FIG. 20 contains a plurality of intermediate stacked structures in which the second semiconductor region 30 is stacked on the first semiconductor region 20. The semiconductor device 1A illustrated in FIG. 20 differs from the semiconductor device 1A illustrated in FIG. 14 in that intermediate stacked structures are arranged in multiple layers in the intermediate region 25. Below, the intermediate stacked structure closer to the semiconductor substrate 10 will be referred to as the “lower layer,” and the intermediate stacked structure closer to the third semiconductor region 40 will be referred to as the “upper layer.”

The semiconductor device 1A illustrated in FIG. 20 includes multiple embedded regions 15 that are respectively connected to the first semiconductor regions 20 included in the plurality of intermediate stacked structures. As illustrated in FIG. 20, multiple embedded regions 15 are arranged in a plan view, such that the embedded region 15 connected to the first semiconductor region 20 closer to the semiconductor substrate 10 is located on the outer side. FIG. 21 is a plan view of the semiconductor device 1A illustrated in FIG. 20. FIG. 20 is a cross-sectional view along the line XX-XX of FIG. 21.

In the semiconductor device 1A of FIG. 20, in addition to the PIN diode P and Zener diode Z included in the semiconductor device 1A of FIG. 14, a third PIN diode P3 and a fourth PIN diode P4 are formed within the intermediate region 25. More specifically, the first semiconductor region 20 of the lowermost layer of the intermediate region 25 forms the first Zener diode Z1 with the semiconductor substrate 10. The first semiconductor region 20 of the lower layer and the second semiconductor region 30 of the lower level form the first PIN diode P1. The third semiconductor region 40 forms the second PIN diode P2 with the second semiconductor region 30 of the uppermost layer of the intermediate region 25. The fourth semiconductor region 50 and the third semiconductor region 40 form the second Zener diode Z2. The third PIN diode P3 is configured with the second semiconductor region 30 of the lower layer as the cathode and the first semiconductor region 20 of the upper layer as the anode. The fourth PIN diode P4 is configured with the first semiconductor region 20 of the upper layer as the anode and the second semiconductor region 30 of the upper layer as the cathode.

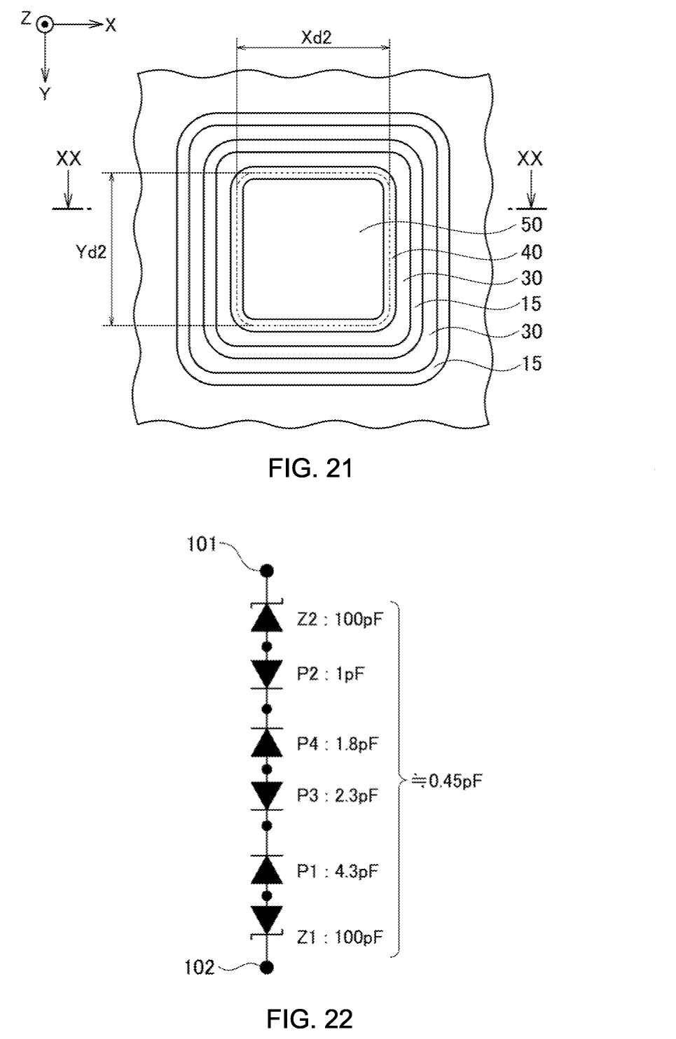

FIG. 22 illustrates an equivalent circuit diagram constituted of PIN diodes P and Zener diodes Z included in the semiconductor device 1A of FIG. 20. The cathode of the second Zener diode Z2 is connected to the first external terminal 101, and the anode of the second Zener diode Z2 is connected to the anode of the second PIN diode P2. The cathode of the second PIN diode P2 is connected to the cathode of the fourth PIN diode P4, and the anode of the fourth PIN diode P4 is connected to the anode of the third PIN diode P3. The cathode of the third PIN diode P3 is connected to the cathode of the first PIN diode P1, and the anode of the first PIN diode P1 is connected to the anode of the first Zener diode Z1. The cathode of the first Zener diode Z1 is connected to the second external terminal 102.

As illustrated in FIG. 20, the area of the fourth PIN diode P4 is larger than that of the second PIN diode P2. Furthermore, the area of the third PIN diode P3 is larger than that of the fourth PIN diode P4, and the area of the first PIN diode P1 is larger than that of the third PIN diode P3. Therefore, the capacitance value of the fourth PIN diode P4 is larger than that of the second PIN diode P2, the capacitance value of the third PIN diode P3 is larger than that of the fourth PIN diode P4, and the capacitance value of the first PIN diode P1 is larger than that of the third PIN diode P3. The capacitance values of the PIN diodes P and Zener diodes Z included in the semiconductor device 1A are as shown in FIG. 22. That is, the capacitance value of the Zener diode Z is approximately 100pF. The capacitance value of the second PIN diode P2 is approximately 1pF, and the capacitance value of the fourth PIN diode P4 is approximately 1.8pF. The capacitance value of the third PIN diode P3 is approximately 2.3pF, and the capacitance value of the first PIN diode P1 is approximately 4.3pF. Therefore, the total capacitance value of the semiconductor device 1A is approximately 0.45pF. By arranging the intermediate stacked structures in multiple layers in the intermediate region 25 in this manner, the capacitance value can be reduced compared to the case where there is only one layer of the intermediate stacked structure.

In the semiconductor device 1A shown in FIG. 20, when a voltage is applied to the first external terminal 101 or the second external terminal 102, the second semiconductor region 30 is completely depleted, similar to the operation described with reference to FIGS. 18 and 19. That is, when a positive voltage is applied to the first external terminal 101, the width of the depletion layer closer to the second external terminal 102 increases, among the depletion layers formed at the interfaces between the second semiconductor region 30 and the P type semiconductor regions. By the deletion layer formed at each interface of the first semiconductor region 20 and the second semiconductor region 30 extending upwardly, all of the second semiconductor regions 30 are completely depleted. When a positive voltage is applied to the second external terminal 102, the width of the depletion layer closer to the first external terminal 101 increases, among the depletion layers formed at the interfaces between the second semiconductor region 30 and the P type semiconductor regions. The depletion layer formed at the interface of the third semiconductor region 40 and the second semiconductor region 30 at the uppermost layer of the intermediate region 25 and the depletion layer formed at the interface of the first semiconductor region 20 and the second semiconductor region 30 in the intermediate region 25 extend downwardly, making all of the second semiconductor regions 30 completely depleted.

With all of the second semiconductor regions 30 completely depleted, the entire second semiconductor region 25 and third semiconductor region 40 become electrically equivalent to the P type regions. As a result, the entire semiconductor body 100 can be considered an NPN transistor. As a result, when a large positive voltage is applied to the first external terminal 101, the NPN transistor undergoes a breakdown operation, and breakdown current flows from the first external terminal 101 to the second external terminal 102. Also, when a large positive voltage is applied to the second external terminal 102, the NPN transistor undergoes a breakdown operation, and breakdown current flows from the second external terminal 102 to the first external terminal 101. As a result of the operations described above, the semiconductor device 1A functions as an overvoltage protection element.

According to the semiconductor device 1A illustrated in FIG. 20, by configuring the intermediate region to have a multiple layers of intermediate stacked structures, the capacitance value can further be reduced. Although the example above illustrates a case where the intermediate region 25 includes two layers of the intermediate stacked structures, three or more layers of the intermediate stacked structures may be used. The greater the number of layers of the intermediate stacked structures, the smaller the capacitance value can be.

### Modification Example 2

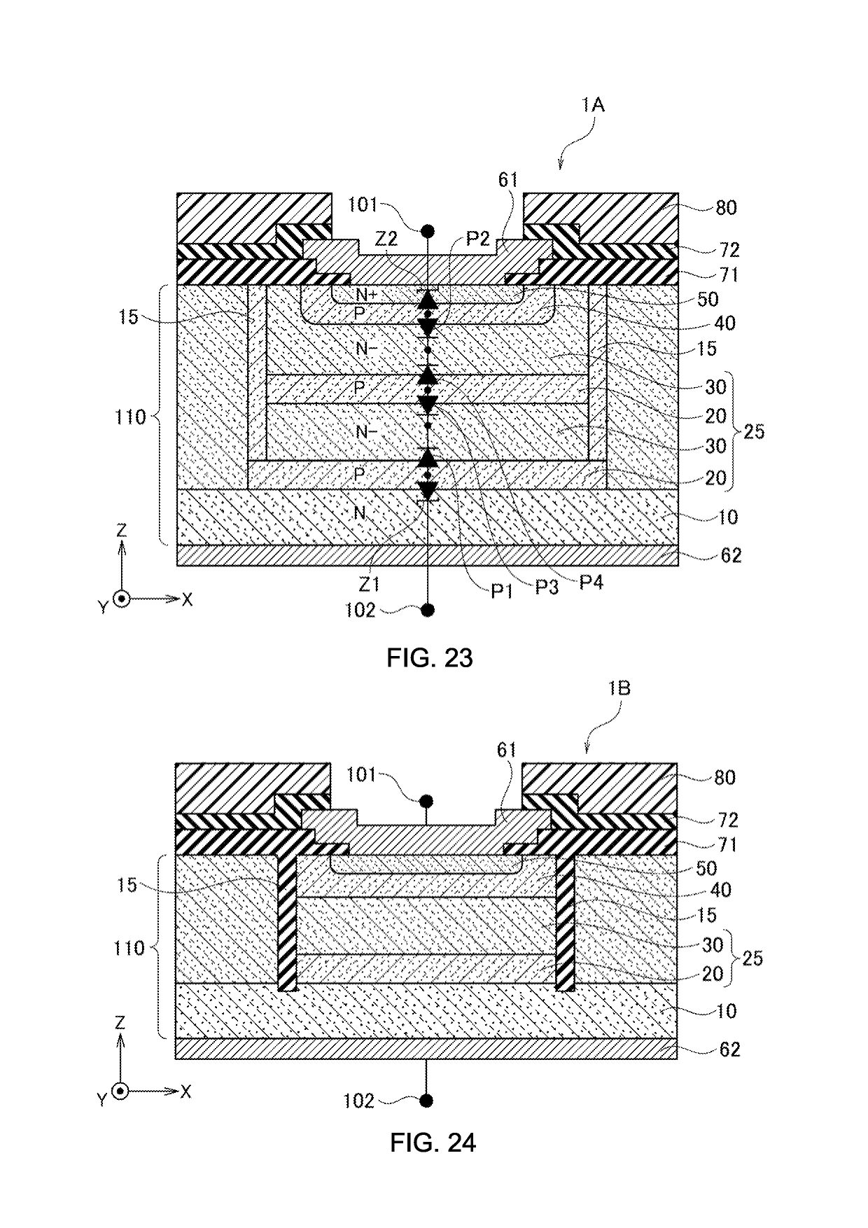

The semiconductor device 1A of Modification Example 1 illustrated in FIG. 20 includes multiple embedded regions 15 that are respectively connected to the first semiconductor regions 20 included in the plurality of intermediate stacked structures. On the other hand, the semiconductor device 1A of Modification Example 2 illustrated in FIG. 23 includes one embedded region 15, and terminals of the respective first semiconductor regions 20 of the plurality of intermediate stacked structures are connected to the same embedded region 15.

With the semiconductor device 1A of FIG. 23, it is possible to make the element area smaller than that of the semiconductor device 1A of FIG. 20. The other configurations of the semiconductor device 1A of FIG. 23 are the same as those of the semiconductor device 1A of FIG. 20, and therefore, duplicate explanations are omitted.

### Embodiment 3

FIG. 24 illustrates a semiconductor device 1B according to Embodiment 3. The semiconductor device 1B differs from the semiconductor device 1A of FIG. 14 in that the embedded region 15 is an insulator, and runs through the intermediate region 25 to reach the semiconductor substrate 10. Other configurations of the semiconductor device 1B are the same as those of Embodiment 2 illustrated in FIG. 14.

The embedded region 15 may be an SiO₂ film, for example. To make the embedded region 15 of an insulator, for example, a groove may be formed from the upper surface of the semiconductor body 100, and the inside of the groove may be filled with an insulating material. The depth of this groove may be 6μm to 35μm, for example, and the width may be 1μm to 6μm, for example.

The semiconductor device 1B has a layered structure in which the semiconductor substrate 10, the intermediate region 25 having a stacked structure where the first semiconductor region 20 and the second semiconductor region 30 are stacked, the third semiconductor region 40, and the fourth semiconductor region 50 are stacked in this order. Furthermore, the semiconductor device 1B includes the embedded region 15 disposed to surround the third semiconductor region 40 and in contact with the semiconductor substrate 10. The fourth semiconductor region 50 and the third semiconductor region 40 form a Zener diode. The third semiconductor region 40 forms a PIN diode with the second semiconductor region 30, which is the uppermost layer of the intermediate region 25. The first semiconductor region 20 and the second semiconductor region 30 constitute a PIN diode. The first semiconductor region 20, which is the lowermost layer of the intermediate region 25, forms a Zener diode with the semiconductor substrate 10.

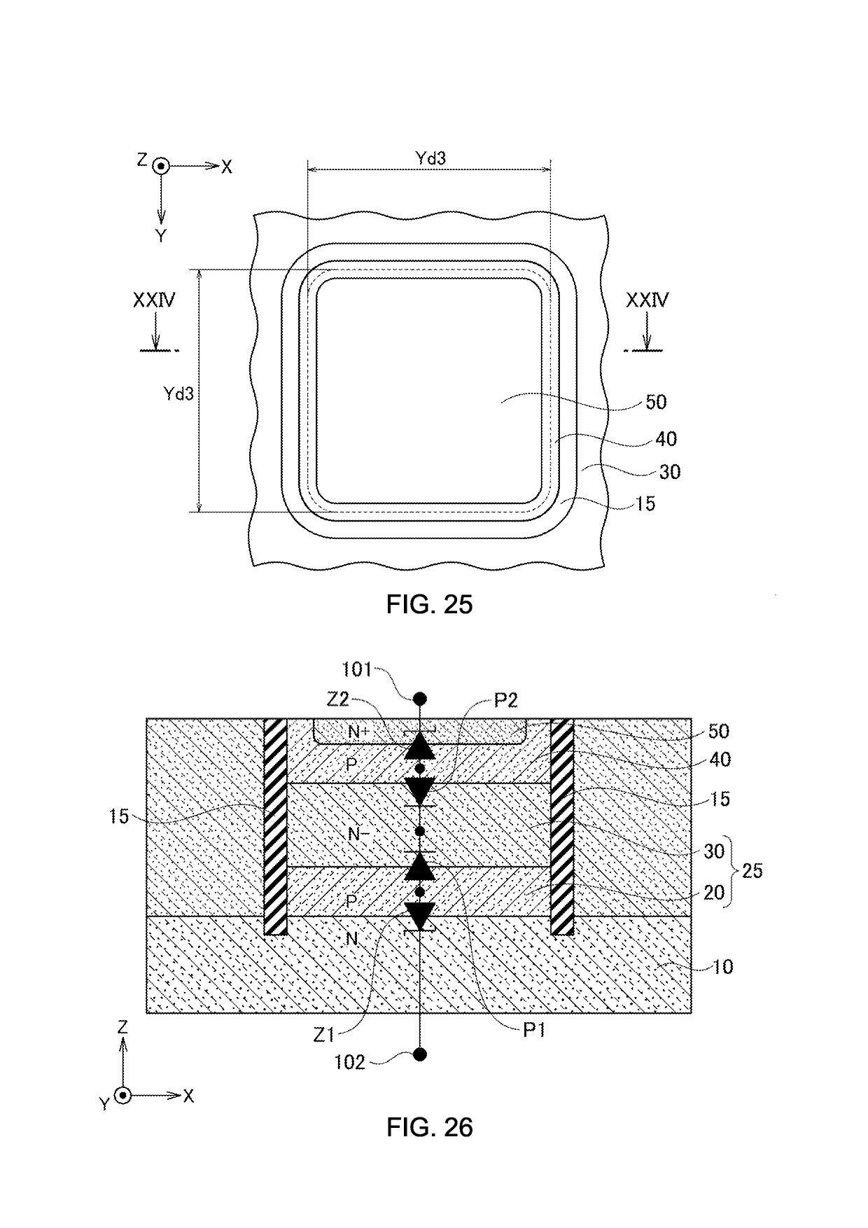

FIG. 25 is a plan view of the semiconductor device 1B illustrated in FIG. 24. FIG. 24 is a cross-sectional view along the line XXIV-XXIV of FIG. 25. In FIG. 25, the X-direction distance Xd3 is the length of the upper metal layer 61 along the X direction, and the Y-direction distance Yd3 is the length of the upper metal layer 61 along the Y direction. In Embodiment 3, Xd3 = 140μm and Yd3 = 140μm.

FIG. 26 illustrates the semiconductor body 100 of the semiconductor device 1B where the first conductivity type is N type and the second conductivity type is P type. As illustrated in FIG. 26, a first Zener diode Z1 is configured with the first semiconductor region 20 as the anode and the semiconductor substrate 10 as the cathode. The first PIN diode P1 is configured with the first semiconductor region 20 as the anode and the second semiconductor region 30 as the cathode. The second PIN diode P2 is configured with the third semiconductor region 40 as the anode and the second semiconductor region 30 as the cathode. The second Zener diode Z2 is configured with the third semiconductor region 40 as the anode and the fourth semiconductor region 50 as the cathode.

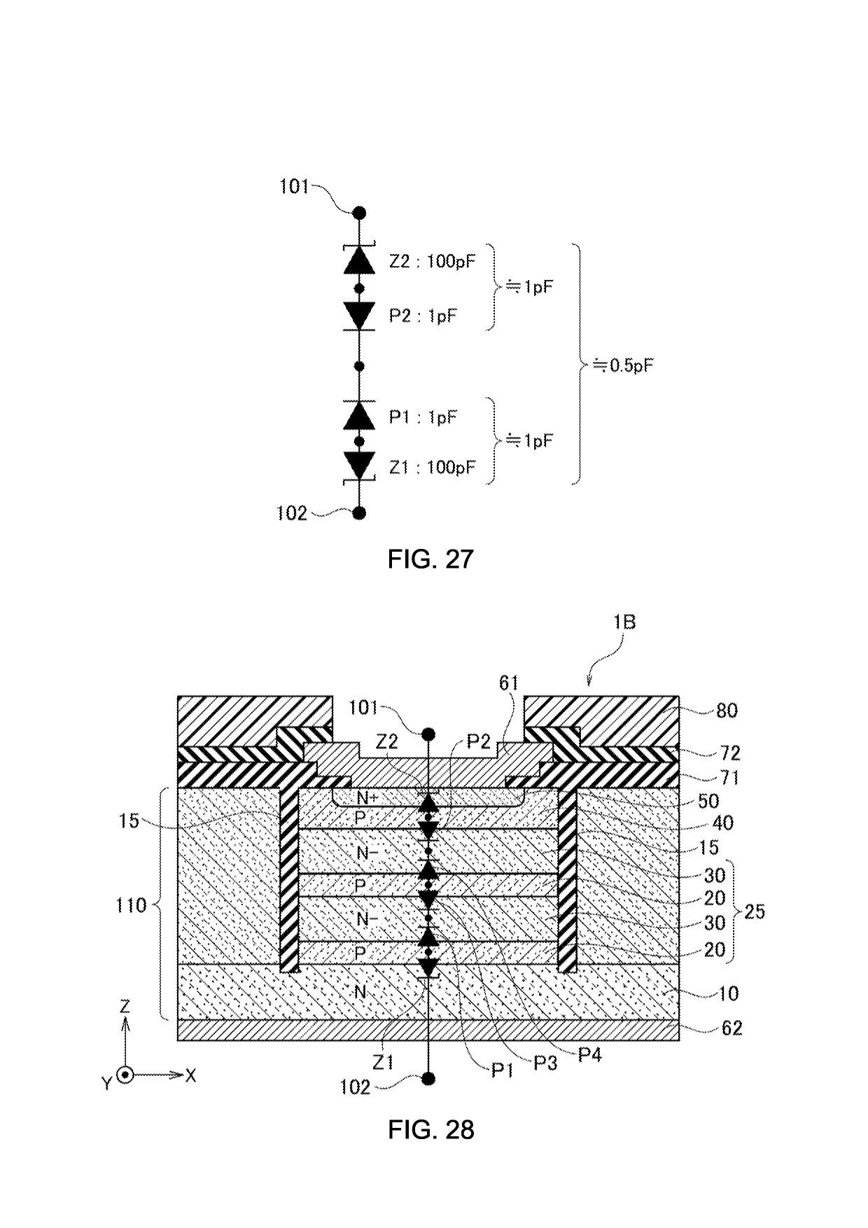

FIG. 27 illustrates an equivalent circuit diagram constituted of the PIN diodes P and Zener diodes Z included in the semiconductor device 1B. The cathode of the second Zener diode Z2 is connected to the first external terminal 101, and the anode of the second Zener diode Z2 is connected to the anode of the second PIN diode P2. The cathode of the second PIN diode P2 is connected to the cathode of the first PIN diode P1, and the anode of the first PIN diode P1 is connected to the anode of the first Zener diode Z1. The cathode of the first Zener diode Z1 is connected to the second external terminal 102. The capacitance values of the first Zener diode Z1 and the second Zener diode Z2 are 100pF, and the capacitance values of the first PIN diode P1 and the second PIN diode P2 are 1pF. Therefore, the total capacitance value of the semiconductor device 1B is approximately 0.5pF. The semiconductor device 1B, which uses an insulator for the embedded region 15, has a smaller total capacitance value than that of the semiconductor device 1A.

The basic operation of the semiconductor device 1B is the same as that of the semiconductor device 1A described with reference to FIGS. 18 and 19. That is, when a positive voltage is applied to the first external terminal 101, the depletion layer formed at the interface of the first semiconductor region 20 and the second semiconductor region 30 extends upwardly. This makes all of the second semiconductor regions 30 completely depleted. Also, when a positive voltage is applied to the second external terminal 102, the depletion layer formed at the interface of the third semiconductor region 40 and the second semiconductor region 30 of the uppermost layer of the intermediate region 25 extends downwardly. This makes all of the second semiconductor regions 30 completely depleted.

With all of the second semiconductor regions 30 completely depleted, the entire second semiconductor region 25 and third semiconductor region 40 become electrically equivalent to the P type regions. As a result, the entire semiconductor body 100 can be considered an NPN transistor. When a large positive voltage is applied to the first external terminal 101, the NPN transistor undergoes a breakdown operation, and breakdown current flows from the first external terminal 101 to the second external terminal 102. Also, when a large positive voltage is applied to the second external terminal 102, the NPN transistor undergoes a breakdown operation, and breakdown current flows from the second external terminal 102 to the first external terminal 101. As a result of the operations described above, the semiconductor device 1B functions as an overvoltage protection element.

As described above, the semiconductor device 1B of Embodiment 3 can reduce the device area while maintaining a low capacitance value and ensuring ESD and surge resistance by stacking the PIN diode P and the Zener diode Z vertically. Furthermore, in the semiconductor device 1B, in which the embedded region 15 is an insulator, the P type region has a smaller area than that of the semiconductor device 1A in which the embedded region 15 is a P type region. Therefore, the semiconductor device 1B can achieve an even smaller capacitance value as compared with the semiconductor device 1A.

### Modification Example 1

FIG. 28 illustrates the semiconductor device 1B according to Modification Example 1 of Embodiment 3. The intermediate region 25 illustrated in FIG. 28 contains a plurality of intermediate stacked structures in which the second semiconductor region 30 is stacked on the first semiconductor region 20. That is, the semiconductor device 1B of FIG. 28 differs from the semiconductor device 1B illustrated in FIG. 24 in that the intermediate region 25 has a structure where a plurality of intermediate stacked structures are layered. The embedded region 15 runs through the plurality of intermediate stacked structures continuously.

In the semiconductor device 1B of FIG. 28, in addition to the PIN diode P and Zener diode Z included in the semiconductor device 1B of FIG. 26, a third PIN diode P3 and a fourth PIN diode P4 are formed within the intermediate region 25. More specifically, the first semiconductor region 20 of the lowermost layer of the intermediate region 25 forms the first Zener diode Z1 with the semiconductor substrate 10. The first semiconductor region 20 of the lower layer and the second semiconductor region 30 of the lower layer form the first PIN diode P1. The third semiconductor region 40 forms the second PIN diode P2 with the second semiconductor region 30 of the uppermost layer of the intermediate region 25. The fourth semiconductor region 50 and the third semiconductor region 40 form the second Zener diode Z2. The third PIN diode P3 is configured with the second semiconductor region 30 of the lower layer as the cathode and the first semiconductor region 20 of the upper layer as the anode. The fourth PIN diode P4 is configured with the first semiconductor region 20 of the upper layer as the anode and the second semiconductor region 30 of the upper layer as the cathode.

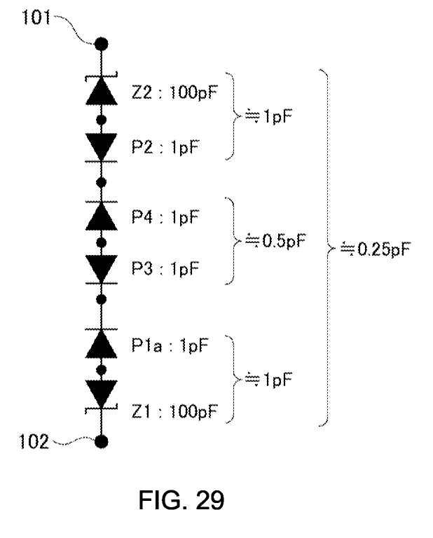

FIG. 29 illustrates an equivalent circuit diagram constituted of PIN diodes P and Zener diodes Z included in the semiconductor device 1B of FIG. 28. The capacitance values of the first Zener diode Z1 and the second Zener diode Z2 are 100pF, and the capacitance values of the first PIN diode P1a, the second PIN diode P2, the third PIN diode P3, and the fourth PIN diode P4 are 1pF. In this case, the total capacitance value of the semiconductor device 1B is approximately 0.25pF. With the semiconductor device 1B including the intermediate region 25 in which a plurality of layers of the intermediate stacked structures, the total capacitance value can further be reduced from that of the semiconductor device 1B of FIG. 24.

In the semiconductor device 1B shown in FIG. 28, when a voltage is applied to the first external terminal 101 or the second external terminal 102, the second semiconductor region 30 is completely depleted, similar to the operation described with reference to FIGS. 18 and 19. That is, when a positive voltage is applied to the first external terminal 101, the depletion layer formed at the interface of the first semiconductor region 20 and the second semiconductor region 30 extends upwardly. This makes all the second semiconductor regions 30 completely depleted. Also, when a positive voltage is applied to the second external terminal 102, the depletion layer formed at the interface of the third semiconductor region 40 and the second semiconductor region 30 at the uppermost layer of the intermediate region 25 and the depletion layer formed at the interface of the first semiconductor region 20 and the second semiconductor region 30 in the intermediate region 25 extend downwardly. This makes all of the second semiconductor regions 30 completely depleted.

With all of the second semiconductor regions 30 completely depleted, the entire intermediate region 25 and third semiconductor region 40 become electrically equivalent to the P type region. As a result, the entire semiconductor body 100 can be considered an NPN transistor. When a large positive voltage is applied to the first external terminal 101, the NPN transistor undergoes a breakdown operation, and breakdown current flows from the first external terminal 101 to the second external terminal 102. Also, when a large positive voltage is applied to the second external terminal 102, the NPN transistor undergoes a breakdown operation, and breakdown current flows from the second external terminal 102 to the first external terminal 101. As a result of the operations described above, the semiconductor device 1B functions as an overvoltage protection element.

According to the semiconductor device 1B illustrated in FIG. 28, by using an insulator for the embedded region 15 and configuring the intermediate region to have multiple layers of intermediate stacked structures, the capacitance value can further be reduced. Also, in the semiconductor device 1A of FIG. 20, having a plurality of intermediate stacked structures would increase the device area, but in the semiconductor device 1B, a plurality of layers of intermediate stacked structures can be arranged without increasing the area. Although the example above illustrates a case where the intermediate region 25 includes two layers of the intermediate stacked structures, three or more layers of the intermediate stacked structures may be arranged.

### Modification Example 2

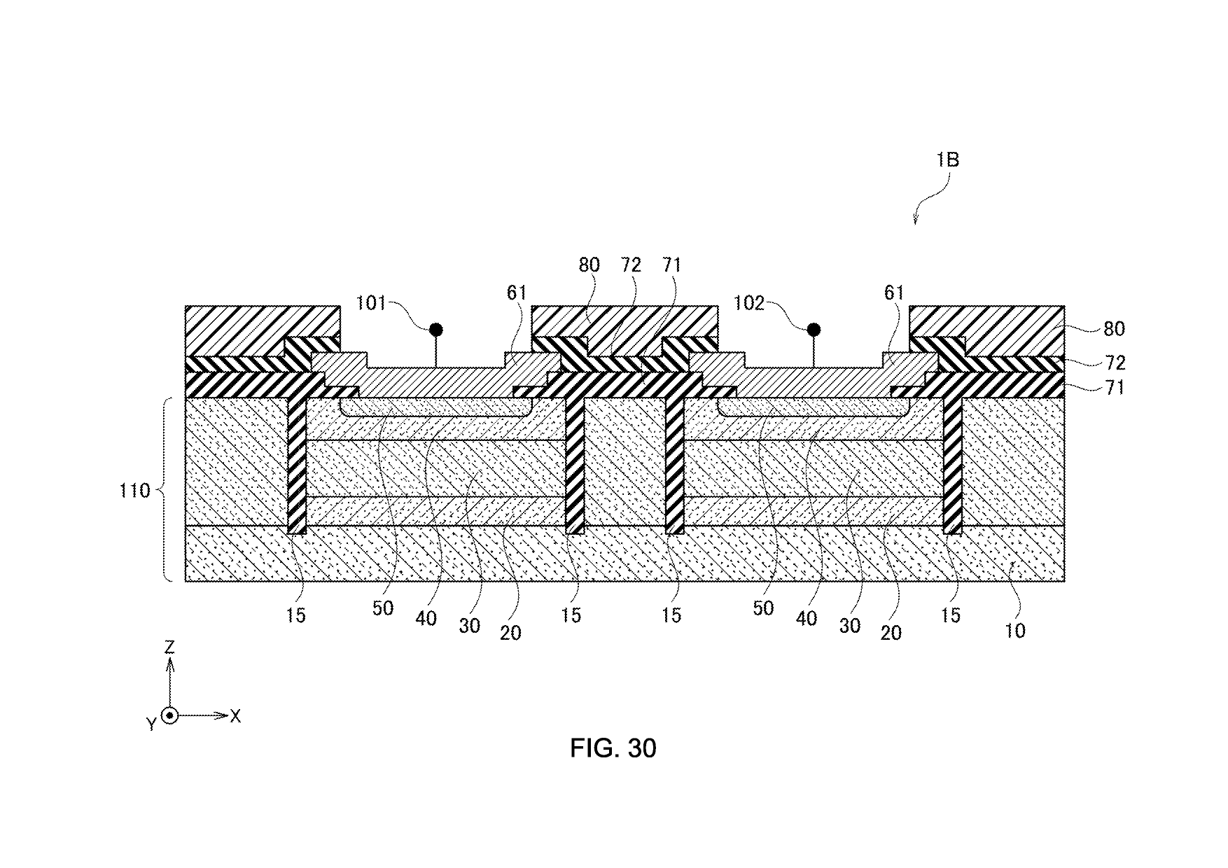

FIG. 30 illustrates the semiconductor device 1B according to Modification Example 2 of Embodiment 3. The semiconductor device 1B illustrated in FIG. 30 has a configuration in which two semiconductor bodies 100 each including the semiconductor substrate 10, the first semiconductor region 20, the second semiconductor region 30, the third semiconductor region 40, and the fourth semiconductor region 50 are connected in series in opposite directions. In the semiconductor device 1B of FIG. 30, the two semiconductor bodies 100 share one semiconductor substrate 10. The upper metal layer 61 disposed on one semiconductor body 100 is connected to the first external terminal 101, and the upper metal layer 61 disposed on the other semiconductor body 100 is connected to the second external terminal 102.

The semiconductor device 1B of FIG. 30 does not have the lower electrode layer 62, and two external terminals are connected to the upper metal layers 61. The structure of the semiconductor device 1B of FIG. 30 is equivalent to a structure in which the semiconductor devices 1B of FIG. 24 are connected in series. Therefore, the capacitance value becomes half that of the semiconductor device 1B of FIG. 24, allowing for further reduction in capacitance value. For example, if the capacitance value of the semiconductor device 1B of FIG. 24 is 0.5pF, then the capacitance value of the semiconductor device 1B of FIG. 30 is 0.25pF. In the semiconductor device 1B of FIG. 30, the intermediate region 25 may have a plurality of layers of intermediate stacked structures, similar to the semiconductor device 1B of FIG. 28.

### Other Embodiments

Although the embodiments have been described as above, the descriptions and drawings that form part of this disclosure should not be understood as limiting the embodiments. From this disclosure, various alternative embodiments, examples, and operating techniques will become apparent to those skilled in the art.

For example, although the descriptions above illustrate the case where the first conductivity type is N type and the second conductivity type is P type, the first conductivity type may be P type and the second conductivity type may be N type. In other words, the semiconductor substrate 10 may be a P type semiconductor, the first semiconductor region 20 may be an N type semiconductor, the second semiconductor region 30 may be a P type or intrinsic semiconductor (i-type), the third semiconductor region 40 may be an N type semiconductor, and the fourth semiconductor region 50 may be a P type semiconductor.

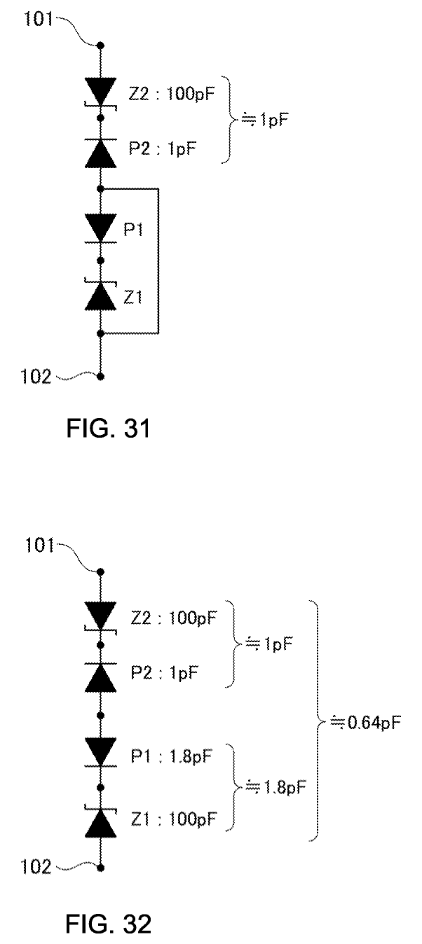

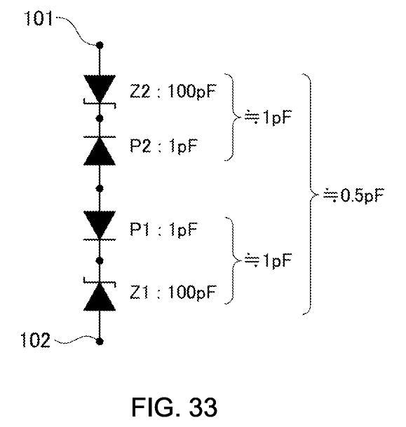

FIG. 31 to 33 are equivalent circuit diagrams constituted of the PIN diode P and Zener diode Z included in semiconductor devices 1, 1A, and 1B, where the first conductivity type is P type and the second conductivity type is N type. FIG. 31 is an equivalent circuit diagram of the semiconductor device 1 illustrated in FIG. 1. FIG. 32 is an equivalent circuit diagram of the semiconductor device 1A illustrated in FIG. 14. FIG. 33 is an equivalent circuit diagram of the semiconductor device 1B illustrated in FIG. 24. The capacitance values of the PIN diode P and the Zener diode Z are the same, regardless of whether the first conductivity type is N type and the second conductivity type is P type, or the first conductivity type is P type and the second conductivity type is N type. Even when the first conductivity type is P type and the second conductivity type is N type, the operation of the semiconductor devices 1, 1A, and 1B when a large voltage (e.g., a surge voltage) is applied to the external terminals is the same as the operation described above for the case where the first conductivity type is N type and the second conductivity type is P type.

Although the present disclosure has been described in detail above, it will be apparent to those skilled in the art that the present disclosure is not limited to the embodiments described herein. One or more elements of one embodiment may be combined with one or more elements of another embodiment. This disclosure may be implemented with modifications and variations without departing from the spirit and scope of the present disclosure as defined by the claims. Therefore, the description in this disclosure is for illustrative purposes only and should not be construed as limiting the scope of this disclosure in any way.

### Supplementary Notes

The technical concepts that can be understood from the present disclosure are described below. For the purpose of aiding understanding, and not with the intention of limiting the scope, the components described in the supplementary notes are provided with reference characters corresponding to the respective components in the embodiments. Reference characters are shown as examples to aid in understanding, and components described in each supplementary note should not be limited to the components indicated by the reference characters.

### Supplementary Note 1

A semiconductor device includes a semiconductor substrate 10 of a first conductivity type; a first semiconductor region 20 of a second conductivity type disposed on the top surface of the semiconductor substrate 10; a second semiconductor region 30 having a conductivity type differing from that of the first conductivity type, disposed on the semiconductor substrate 10 to cover the first semiconductor region 10; a third semiconductor region 40 of the second conductivity type disposed on the top surface of the second semiconductor region 30; and a fourth semiconductor region 50 of the first conductivity type embedded in a portion of the top part of the third semiconductor region 40. The semiconductor substrate 10 and the first semiconductor region 20 constitute a Zener diode. The second semiconductor region 30 and the first semiconductor region 20 form a PIN diode. The third semiconductor region 40 is disposed on the second semiconductor region 30 to face the first semiconductor region 20 through the second semiconductor region 30, forming a PIN diode with the second semiconductor region 30. The fourth semiconductor region 50 and the third semiconductor region 40 form a Zener diode. The impurity concentration of the second semiconductor region 30 is lower than the impurity concentrations of the first semiconductor region 20 and the third semiconductor region 40.

According to the semiconductor device of Supplementary Note 1, the PIN diode and Zener diode are stacked together, which makes it possible to reduce the device area while maintaining a low capacitance value and ensuring ESD and surge resistance.

### Supplementary Note 2

In the semiconductor device according to Supplementary Note 1, the impurity concentrations of the first semiconductor region 20, the second semiconductor region 30, and the third semiconductor region 40 are set such that a depletion layer is formed from the top surface to the bottom surface of the second semiconductor region 30 when a predetermined voltage is applied between the semiconductor substrate 10 and the fourth semiconductor region 50.

According to the semiconductor device of Supplementary Note 2, when a large positive voltage is applied to the external terminal, the second semiconductor region 30 is completely depleted, which makes the second semiconductor region 30 and third semiconductor region 40 electrically equivalent to the P type region. As a result, the entire semiconductor body 100 can be considered an NPN transistor. Therefore, when a large voltage is applied to the external terminal, the NPN transistor undergoes a breakdown operation, causing breakdown current to flow.

### Supplementary Note 3

The second semiconductor region 30 of the semiconductor device according to Supplementary Note 1 or 2 is of the first conductivity type.

### Supplementary Note 4

The second semiconductor region 30 of the semiconductor device according to Supplementary Note 1 or 2 is an intrinsic semiconductor.

### Supplementary Note 5

In the semiconductor device according to any one of Supplementary Notes 1 to 4, the second semiconductor region 30 is connected to the semiconductor substrate 10 outside the first semiconductor region 20.

According to the semiconductor device of Supplementary Note 5, when a large positive voltage is applied to the first external terminal 101, the NPN transistor, which is constituted of the fourth semiconductor region 50, the third semiconductor region 40, and the second semiconductor region 30, undergoes a breakdown operation, causing electric current to flow.

### Supplementary Note 6

In the semiconductor device according to any one of Supplementary Notes 1 to 5, the third semiconductor region 40 is embedded in a portion of the upper part of the second semiconductor region 30.

### Supplementary Note 7

A semiconductor device includes a semiconductor substrate 10 of a first conductivity type; an intermediate region 25 disposed on the top surface of the semiconductor substrate 10; a third semiconductor region 40 of the second conductivity type embedded in the top part of the second semiconductor region 30 of the uppermost layer of the intermediate region 25; a fourth semiconductor region 50 of the first conductivity type embedded in a portion of the top part of the third semiconductor region 40. An embedded region 15 is arranged to surround the third semiconductor region 40 without being electrically connected thereto, the embedded region 15 extending from the top surface of the intermediate region 25 toward the semiconductor substrate 10 in such a manner that it defines the extent of the second semiconductor region 30 in a plan view. The intermediate region 25 includes at least one stacked structure in which the first semiconductor region 20 of the second conductivity type has stacked thereon the second semiconductor region 30 having a conductivity type differing from that of the first semiconductor region 20.

The first semiconductor region 20 of the lowermost layer forms a Zener diode with the semiconductor substrate 10, and the first semiconductor region 20 and the second semiconductor region 30 form a PIN diode. The third semiconductor region 40 faces the semiconductor substrate 10 through the intermediate region 25, forming a PIN diode with the second semiconductor region 30, which is the uppermost layer of the intermediate region 25. The fourth semiconductor region 50 and the third semiconductor region 40 form a Zener diode. The impurity concentration of the second semiconductor region 30 is lower than the impurity concentrations of the first semiconductor region 20 and the third semiconductor region 40.

According to the semiconductor device of Supplementary Note 7, the PIN diode and Zener diode are stacked together, which makes it possible to reduce the device area while maintaining a low capacitance value and ensuring ESD and surge resistance. Furthermore, with the semiconductor device including the embedded region 15, it is possible to reduce the capacitance value even further.

### Supplementary Note 8

In the semiconductor device according to Supplementary Note 7, the impurity concentrations of the first semiconductor region 20, the second semiconductor region 30, and the third semiconductor region 40 are set such that a depletion layer is formed from the bottom surface to the top surface of the second semiconductor region 30 when a predetermined voltage is applied between the semiconductor substrate 10 and the fourth semiconductor region 50.

According to the semiconductor device of Supplementary Note 8, when a large positive voltage is applied to the external terminal, the second semiconductor region 30 is completely depleted, which makes the second semiconductor region 30 and third semiconductor region 40 electrically equivalent to the P type region. As a result, the entire semiconductor body 100 can be considered an NPN transistor. Therefore, when a large voltage is applied to the external terminal, the NPN transistor undergoes a breakdown operation, causing breakdown current to flow.

### Supplementary Note 9

The second semiconductor region 30 of the semiconductor device according to Supplementary Note 7 or 8 is of the first conductivity type.

### Supplementary Note 10

The second semiconductor region 30 of the semiconductor device according to Supplementary Note 7 or 8 is an intrinsic semiconductor.

### Supplementary Note 11

In the semiconductor device according to any one of Supplementary Notes 7 to 10, the embedded region 15 is a semiconductor of the second conductivity type, and the embedded region 15 is connected to the first semiconductor region 20.

### Supplementary Note 12

In the semiconductor device according to Supplementary Note 7, the intermediate region 25 has a layered structure in which a plurality of stacked structures are layered, and the semiconductor device includes a plurality of embedded regions 15 that are respectively connected to the first semiconductor regions 20 included in the plurality of stacked structures. The plurality of embedded regions 15 are arranged in a plan view such that the embedded region 15 connected to the first semiconductor region 20 closer to the semiconductor substrate 10 is located on the outer side.

According to the semiconductor device of Supplementary Note 12, the intermediate region 25 has a multiple layers of stacked structures, which makes it possible to further reduce the capacitance value.

### Supplementary Note 13

In the semiconductor device according to any one of Supplementary Notes 7 to 10,

The embedded region 15 is an insulator, and the embedded region 15 runs through the intermediate region 25 to reach the semiconductor substrate 10.

According to the semiconductor device of Supplementary Note 13,

by using an insulator for the embedded region, the total capacitance value can be reduced.

### Supplementary Note 14

In the semiconductor device according to Supplementary Note 13, the intermediate region 25 has a configuration where a plurality of stacked structures are layered, and the embedded region 15 runs through the plurality of stacked structures continuously.

What is claimed is:

1. A semiconductor device, comprising:
a semiconductor substrate of a first conductivity type;
an intermediate region disposed on a top surface of the semiconductor substrate, the intermediate region including at least one stacked structure in which a first semiconductor region of a second conductivity type has stacked thereon a second semiconductor region having a conductivity type differing from that of the first semiconductor region, such that the first semiconductor region is a lowermost layer that forms a Zener diode with the semiconductor substrate, and the first semiconductor region and the second semiconductor region form a PIN diode;
a third semiconductor region of the second conductivity type embedded in a top part of the second semiconductor region of an uppermost layer of the intermediate region, the third semiconductor region facing the semiconductor substrate through the intermediate region and forming a PIN diode with the second semiconductor region of the uppermost layer; and
a fourth semiconductor region of the first conductivity type embedded in a portion of a top part of the third semiconductor region and forming a Zener diode with the third semiconductor region;
wherein an impurity concentration of the second semiconductor region is lower than impurity concentrations of the first semiconductor region and the third semiconductor region.

2. The semiconductor device according to claim 1, further comprising an embedded region arranged to surround the third semiconductor region without being electrically connected thereto, the embedded region extending from a top surface of the intermediate region toward the semiconductor substrate in such a manner that the embedded region defines an extent of the second semiconductor region in a plan view.

3. The semiconductor device according to claim 1, wherein the impurity concentrations of the first semiconductor region, the second semiconductor region, and the third semiconductor region are set such that a depletion layer is formed from a top surface of the second semiconductor region to a bottom surface of the second semiconductor region when a predetermined voltage is applied between the semiconductor substrate and the fourth semiconductor region.

4. The semiconductor device according to claim 1, wherein the second semiconductor region is of the first conductivity type.

5. The semiconductor device according to claim 1, wherein the second semiconductor region is an intrinsic semiconductor.

6. The semiconductor device according to claim 2, wherein the embedded region is a semiconductor of the second conductivity type, and
wherein the embedded region is connected to the first semiconductor region.

7. The semiconductor device according to claim 6, wherein the intermediate region has a
configuration where a plurality of said stacked structures are layered,
wherein a plurality of said embedded regions are provided to respectively connect to
first semiconductor regions included in the plurality of stacked structures, and
wherein the plurality of embedded regions are arranged in a plan view such that an
embedded region connected to a first semiconductor region closer than another of the first
semiconductor regions to the semiconductor substrate is located on an outer side of the plurality
of stacked structures.

8. The semiconductor device according to claim 2, wherein the embedded region is an
insulator, and
wherein the embedded region runs through the intermediate region to reach the
semiconductor substrate.

9. The semiconductor device according to claim 8, wherein the intermediate region has a configuration where a plurality of said stacked structures are layered, and
wherein the embedded region runs through the plurality of stacked structures continuously.
